(19) United States
(12) Patent Application Publication
(10) Pub. No.: US 2025/0393331 A1
(43) Pub. Date: Dec. 25, 2025

(54) IMAGE SENSOR

(71) Applicant: Samsung Electronics Co., Ltd., Suwon-si (KR)

(72) Inventors: Dongsuk YOO, Suwon-si (KR); Sunghyuck CHO, Suwon-si (KR); Youngsun OH, Suwon-si (KR); Joongseok PARK, Suwon-si (KR); Cheon Ho PARK, Suwon-si (KR); Yoongi JOUNG, Suwon-si (KR); Jooho HWANG, Suwon-si (KR)

(73) Assignee: Samsung Electronics Co., Ltd., Suwon-si (KR)

(21) Appl. No.: 19/222,579

(22) Filed: May 29, 2025

(30) Foreign Application Priority Data
Jun. 24, 2024 (KR) 10-2024-0082175

(51) Int. Cl. H10F 39/00; H10F 39/18

(52) U.S. Cl. CPC H10F 39/811; H10F 39/182; H10F 39/807

(57) ABSTRACT

An image sensor may include a substrate having first and second surfaces opposite to each other, a pixel isolation portion in the substrate and defining large and small light-receiving regions, which are separated from and adjacent to each other, large and small photoelectric conversion parts disposed in the substrate and in the large and small light-receiving regions, respectively, a first dopant region disposed in the substrate to be adjacent to the first surface in the large light-receiving region, a second dopant region disposed in the substrate to be adjacent to the first surface in the small light-receiving region, and a first connection line connecting the first and second dopant regions. The large and small photoelectric conversion parts may be doped with first dopants of a first conductivity type and may have different doping concentrations.

### CROSS-REFERENCE TO RELATED APPLICATIONS

This U.S. non-provisional patent application claims priority under 35 U.S.C. § 119 to Korean Patent Application No. 10-2024-0082175, filed on Jun. 24, 2024, in the Korean Intellectual Property Office, the entire contents of which are hereby incorporated by reference.

### BACKGROUND

Some example embodiments relate to an image sensor.

An image sensor is a semiconductor device converting an optical image to electric signals. The image sensor is classified into two types: a charge coupled device (CCD) type and a complementary metal-oxide-semiconductor (CMOS) type. The CMOS-type image sensor is called CIS for short. The CIS includes a plurality of pixels that are two-dimensionally arranged. Each of the pixels includes a photodiode (PD), which is used to convert incident light to an electric signal.

### SUMMARY

Some example embodiments provide a highly-integrated image sensor capable of obtaining high-quality images.

According to some example embodiments, an image sensor may include a substrate having a first surface and a second surface, which are opposite to each other, a deep isolation pattern in the substrate and defining a large light-receiving region and a small light-receiving region separated from each other, the large light-receiving region adjacent to the small light-receiving region, a first large photoelectric conversion part in the substrate and in the large light-receiving region, a small photoelectric conversion part in the substrate and in the small light-receiving region, a first dopant region in the large light-receiving region, in the substrate, and adjacent to the first surface, a second dopant region in the small light-receiving region in the substrate and adjacent to the first surface, and a first connection line connecting the first dopant region to the second dopant region. The large photoelectric conversion part and the small photoelectric conversion part may be doped with first dopants of a first conductivity type, and a concentration of the first dopant of the first large photoelectric conversion part may be different from a concentration of the first dopant of the small photoelectric conversion part.

Alternatively or additionally according to some example embodiments, an image sensor may include a substrate having a first surface and a second surface, which are opposite to each other, a deep isolation pattern in the substrate and defining a large light-receiving region and a small light-receiving region separated from each other, the large light-receiving region adjacent to the small light-receiving region, a first color filter on the second surface and covering the large light-receiving region and the small light-receiving region, a first micro lens on the first color filter and covering the large light-receiving region, a second micro lens on the first color filter and covering the small light-receiving region, a large photoelectric conversion part in the substrate and in the large light-receiving region, a small photoelectric conversion part in the substrate and in the small light-receiving region, a first dopant region in the substrate, in the large light-receiving region, and adjacent to the first surface, a second dopant region disposed in the substrate, in the small light-receiving region, and adjacent to the first surface, a first connection line connecting the first dopant region to the second dopant region, a large transfer gate electrode in the large light-receiving region and on the first surface and partially inserted into the substrate, a large floating diffusion region in the substrate, a buried region between the large floating diffusion region and the large photoelectric conversion part, and a well region between the first dopant region and the large photoelectric conversion part. The large photoelectric conversion part and the small photoelectric conversion part may be doped with first dopants of a first conductivity type, and the well region and the buried region may be doped with second dopants, which have a second conductivity type different from the first conductivity type. A concentration of the second dopant in the buried region may be lower than a concentration of the second dopant in the well region.

Alternatively or additionally according to some example embodiments, an image sensor may include a substrate having a first surface and a second surface, which are opposite to each other, a deep isolation pattern in the substrate and defining a large light-receiving region and a small light-receiving region separated from each other, the large light-receiving region adjacent to the small light-receiving region, a first dopant region in the substrate, in the large light-receiving region, and adjacent to the first surface, a second dopant region in the substrate, in the small light-receiving region, and adjacent to the first surface, and a first connection line connecting the first dopant region to the second dopant region. An area of the large light-receiving region may be larger than an area of the small light-receiving region. The deep isolation pattern may extend to be inserted into the small light-receiving region and may divide the small light-receiving region into a plurality of sub-small light-receiving regions.

### BRIEF DESCRIPTION OF THE DRAWINGS

FIG. 1 is a block diagram illustrating an image sensor according to some example embodiments.

FIG. 2 is a plan view illustrating a pixel array of an image sensor according to some example embodiments.

FIG. 3A is a layout illustrating an image sensor according to some example embodiments.

FIG. 3B is a sectional view taken along a line A-A′ of FIG. 3A.

FIG. 4A is a circuit diagram illustrating the image sensor of FIG. 3A.

FIG. 4B is a timing diagram illustrating an operation of the image sensor of FIG. 3A.

FIG. 5 is a potential diagram of the image sensor of FIGS. 3A and 3B.

FIG. 6A is a layout illustrating an image sensor according to some example embodiments.

FIG. 6B is a sectional view taken along a line A-A′ of FIG. 6A.

FIG. 7A is a layout illustrating an image sensor according to some example embodiments.

FIG. 7B is a sectional view taken along a line A-A′ of FIG. 7A.

FIG. 8A is a layout illustrating an image sensor according to some example embodiments.

FIG. 8B is a sectional view taken along a line A-A′ of FIG. 8A.

FIG. 9 is a circuit diagram illustrating the image sensor of FIG. 8A.

FIG. 10 is a potential diagram of the image sensor of FIGS. 8A and 8B.

FIG. 11A is a layout illustrating an image sensor according to some example embodiments.

FIG. 11B is a sectional view taken along a line A-A′ of FIG. 11A.

FIG. 12A is a layout illustrating an image sensor according to some example embodiments.

FIG. 12B is a sectional view taken along a line A-A′ of FIG. 12A.

FIG. 13 is a layout illustrating an image sensor according to some example embodiments.

FIG. 14 is a layout illustrating an image sensor according to some example embodiments.

FIG. 15A is a layout illustrating an image sensor according to some example embodiments.

FIG. 15B is a sectional view taken along a line A-A′ of FIG. 15A.

FIG. 16 is a layout illustrating an image sensor according to some example embodiments.

FIG. 17 is a layout illustrating an image sensor according to some example embodiments.

FIG. 18 is a layout illustrating an image sensor according to some example embodiments.

FIG. 19 is a layout illustrating an image sensor according to some example embodiments.

FIG. 20 is a layout illustrating an image sensor according to some example embodiments.

FIG. 21 is a layout illustrating an image sensor according to some example embodiments.

FIG. 22A is a layout illustrating an image sensor according to some example embodiments.

FIG. 22B is a sectional view taken along a line C-C′ of FIG. 22A.

FIG. 23 is a layout illustrating an image sensor according to some example embodiments.

FIG. 24 is a layout illustrating an image sensor according to some example embodiments.

FIG. 25 is a layout illustrating an image sensor according to some example embodiments.

FIG. 26 is a layout illustrating an image sensor according to some example embodiments.

FIG. 27 is a circuit diagram illustrating the image sensor of FIG. 26.

FIG. 28 is a layout illustrating an image sensor according to some example embodiments.

FIG. 29 is a circuit diagram illustrating the image sensor of FIG. 28.

FIG. 30 is a layout illustrating an image sensor according to some example embodiments.

FIG. 31 is a layout illustrating an image sensor according to some example embodiments.

FIG. 32 is a layout illustrating an image sensor according to some example embodiments.

FIG. 33A is a layout illustrating an image sensor according to some example embodiments.

FIG. 33B is a sectional view taken along a line D-D′ of FIG. 33A.

FIG. 34 is a potential diagram illustrating the image sensor of FIG. 33A.

FIG. 35A is a layout illustrating an image sensor according to some example embodiments.

FIG. 35B is a sectional view taken along a line D-D′ of FIG. 35A.

FIG. 36 is a layout illustrating an image sensor according to some example embodiments.

FIG. 37 is a layout illustrating an image sensor according to some example embodiments.

FIG. 38 is a layout illustrating an image sensor according to some example embodiments.

FIG. 39 is a layout illustrating an image sensor according to some example embodiments.

FIG. 40 is a layout illustrating an image sensor according to some example embodiments.

FIG. 41 is a layout illustrating an image sensor according to some example embodiments.

FIG. 42 is a layout illustrating an image sensor according to some example embodiments.

FIG. 43 is a layout illustrating an image sensor according to some example embodiments.

FIGS. 44A to 44M are layouts illustrating an image sensor according to some example embodiments.

FIG. 45 is a sectional view illustrating an image sensor according to some example embodiments.

### DETAILED DESCRIPTION

Some example embodiments will now be described more fully with reference to the accompanying drawings, in which example embodiments are shown. Like reference numerals in the drawings denote like elements, and thus their description will be omitted. As described herein, terms such as first, second, etc., indicating order, are used to distinguish elements that perform the same or similar functions from one another, and their numbering can change according to the mentioned order.

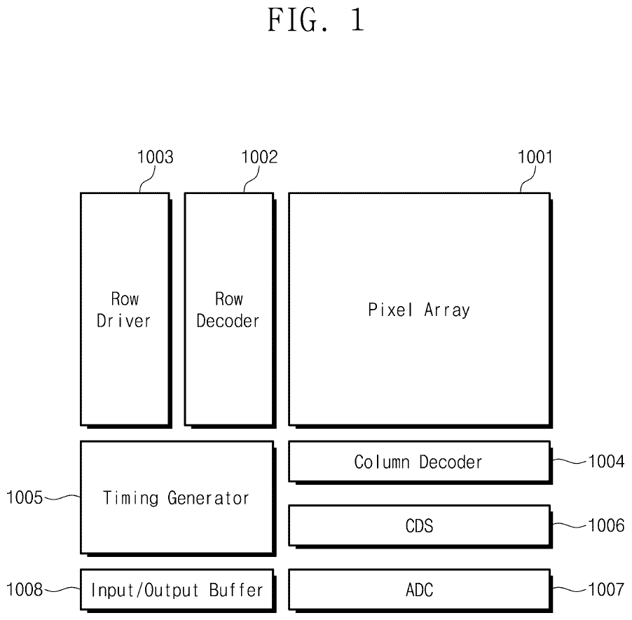

FIG. 1 is a block diagram illustrating an image sensor according to some example embodiments.

Referring to FIG. 1, an image sensor may include a pixel array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

Each of the pixel array 1001, the row decoder 1002, the row driver 1003, the column decoder 1004, the timing generator 1005, the correlated double sampler (CDS) 1006, the analog-to-digital converter (ADC) 1007, and the input/output (I/O) buffer 1008 may communicate with others of the pixel array 1001, the row decoder 1002, the row driver 1003, the column decoder 1004, the timing generator 1005, the correlated double sampler (CDS) 1006, the analog-to-digital converter (ADC) 1007, and the input/output (I/O) buffer 1008 to exchange information over a bus, such as a wired bus. The information may be or may include digital information and/or analog information. The communication may be one-way and/or two-way and/or multiway. The information may be data and/or commands, such as instructions. Example embodiments are not limited thereto.

The pixel array 1001 may include a plurality of unit pixels, which are arranged to form a plurality of rows and a plurality of columns, and the unit pixels may convert an incident light to an electrical signal. A number of the plurality of rows may be the same as, greater than, or less than, a number of the plurality of columns; example embodiments are not limited thereto. The pixel array 1001 may be driven by a plurality of driving signals (e.g., one or more of selection signals, reset signals, and transfer signals) provided from the row decoder 1002.

The row decoder 1002 may be configured to provide driving signals to respective rows of the unit pixels. In addition, the electrical signal, which is produced by the conversion in the pixel array 1001, may be provided to the CDS 1006, in response to the driving signals.

The row driver 1003 may provide a plurality of driving signals, which are used to drive (e.g., to turn on or turn off) the unit pixels, to the pixel array 1001 in accordance with the decoded result obtained from the row decoder 1002. In a case where the unit pixels are arranged in a matrix shape, the driving signals may be applied to the rows of the unit pixels, respectively.

The timing generator 1005 may control each of or at least one of the row and column decoders 1002 and 1004, the CDS 1006, the ADC 1007, and the input/output buffer 1008 and may supply control signals, such as clock signals and timing control signals for operations thereof. The timing generator 1005 may include one or more of a logic control circuit, a phase lock loop (PLL) circuit, a timing control circuit, a communication interface circuit, and so forth.

The CDS 1006 may receive electric signals, which are generated in the pixel array 1001, and may perform operations of holding and sampling the received electric signals. For example, the CDS 1006 may perform a double sampling operation on a specific noise level and a signal level of the electric signal and may output a difference level corresponding to a difference between the noise and signal levels.

The ADC 1007 may convert analog signals, which correspond to the difference level output from the CDS 1006, into digital signals, and then may output the converted digital signals to the I/O buffer 1008.

The I/O buffer 1008 may latch the digital signal, which are output from the ADC 1007, and then may output the latched digital signals sequentially to an image signal processing unit (not shown) in accordance with the decoding result obtained from the column decoder 1004.

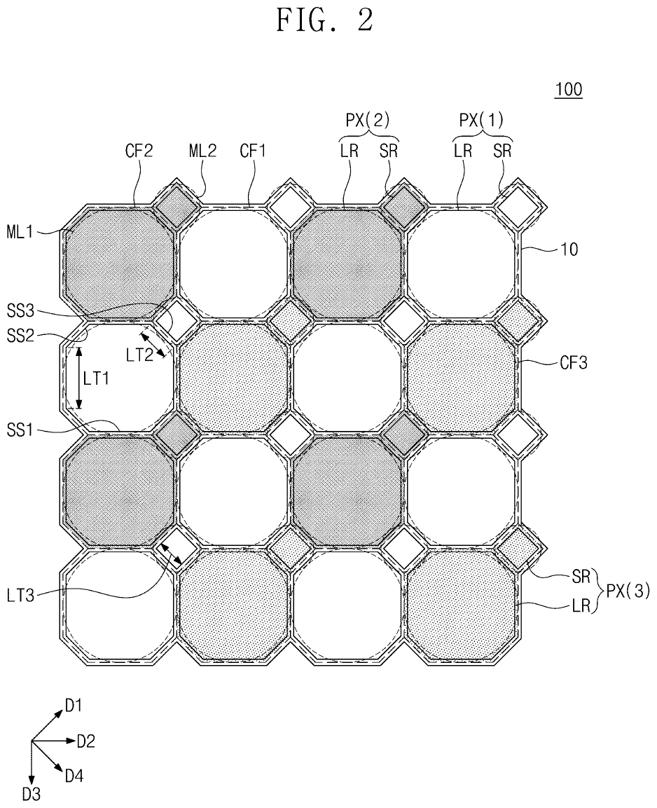

FIG. 2 is a plan view illustrating a pixel array of an image sensor according to some example embodiments.

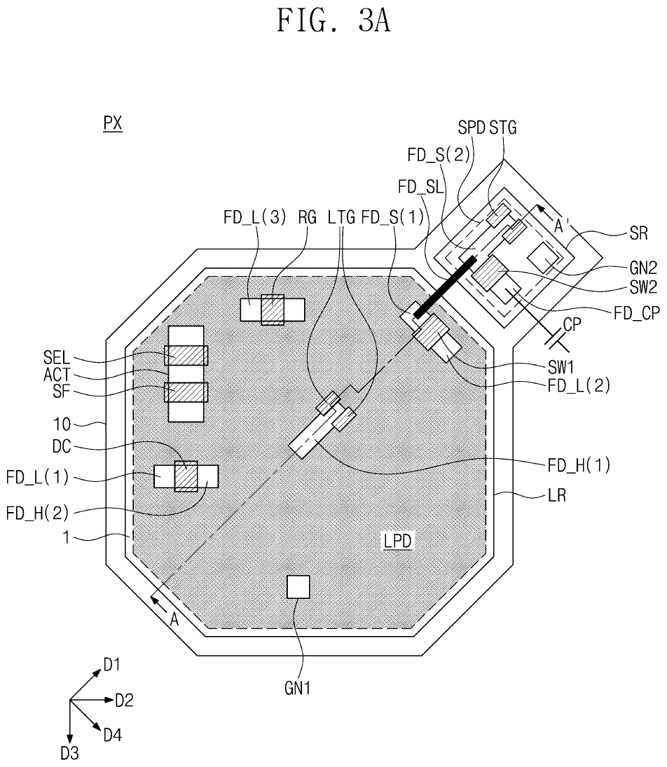

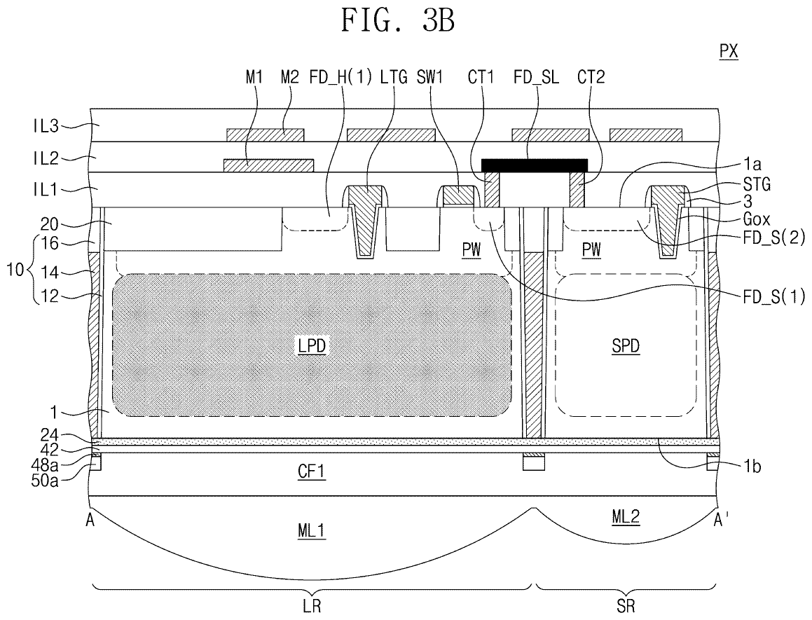

Referring to FIG. 2, in an image sensor 100 in some example embodiments, a deep isolation pattern 10 may be disposed in a substrate 1 (e.g., see FIG. 3B) to separate light-receiving regions LR and SR of a plurality of pixels such as first to third pixels PX(1) to PX(3). The first to third pixels PX(1) to PX(3) may be two-dimensionally arranged in a second direction D2 and a third direction D3 which are orthogonal to each other. The second direction D2 and the third direction D3 may be parallel to a front surface 1a of the substrate 1 (e.g., see FIG. 3B).

The first pixel PX(1) may be covered with a first color filter CF1. The second pixel (PX(2)) may be covered with a second color filter CF2, e.g., transmitting a different color than that of the first color pixel CFL. The third pixel (PX(3)) may be covered with a third color filter CF3 e.g., transmitting a different color than that of the first color pixel CF1 and/or of the second color pixel CF2. One of the first to third color filters CF1 to CF3 may include a red, blue, and green color filters; example embodiments re not limited thereto.

Each of the first to third pixels PX(1) to PX(3) may include a large light-receiving region LR and a small light-receiving region SR disposed in the substrate 1. The deep isolation pattern 10 may be interposed between the large and small light-receiving regions LR and SR. A planar area of the large light-receiving region LR may be larger than a planar area of the small light-receiving region SR. A first micro lens ML1 may be disposed on the large light-receiving region LR. A second micro lens ML2 may be disposed on the small light-receiving region SR. A planar area of the first micro lens ML1 may be larger than a planar area of the second micro lens ML2.

Referring to FIG. 2, directions D1 and D2 may intersect, e.g., at an angle of 45 degrees; example embodiments are not limited thereto. Additionally or alternatively, directions D2 and D4 may intersect, e.g., at an angle of 45 degrees; example embodiments are not limited thereto. Additionally or alternatively, directions D4 and D3 may intersect, e.g., at an angle of 45 degrees; example embodiments are not limited thereto.

In each of the first to third pixels PX(1) to PX(3), the large and small light-receiving regions LR and SR may be arranged side by side in a first direction D1. The large light-receiving region LR may have an octagonal shape, which is formed by alternatively and repeatedly disposing first side surfaces SS1 and second side surfaces SS2, when viewed in a plan view. The small light-receiving region SR may be adjacent to one of the second side surfaces SS2. The small light-receiving region SR may have a rectangular shape, e.g., a square shape, which is composed of third side surfaces SS3, when viewed in a plan view. The first side surface SS1 may have a first length LT1. The second side surface SS2 may have a second length LT2 smaller than the first length LT1. The third side surface SS3 may have a third length LT3, which is equal to or smaller than the second length LT2.

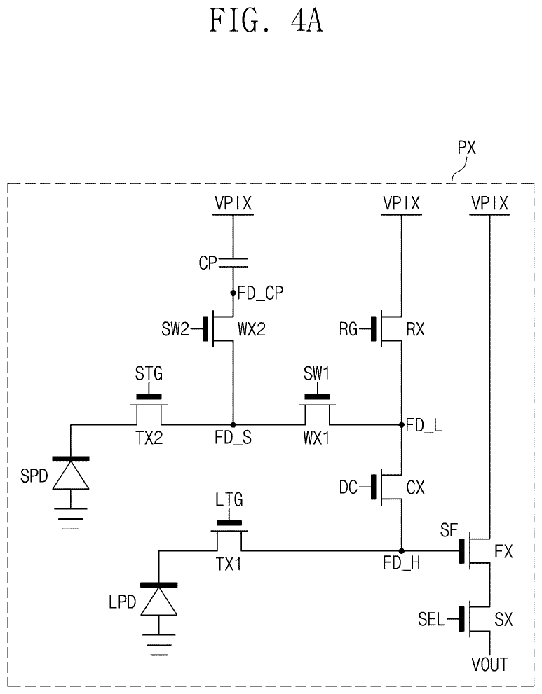

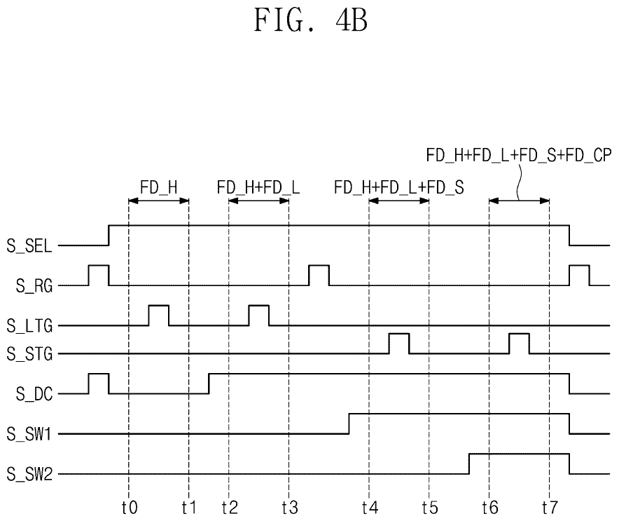

FIG. 3A is a layout illustrating an image sensor according to some example embodiments. FIG. 3B is a sectional view taken along a line A-A′ of FIG. 3A. The layout of FIG. 3A may correspond to one pixel PX of the pixel array of FIG. 2. FIG. 4A is a circuit diagram illustrating the image sensor of FIG. 3A. FIG. 4B is a timing diagram illustrating an operation of the image sensor of FIG. 3A.

Referring to FIGS. 2, 3A, and 3B, the image sensor in some example embodiments may include a substrate 1. The substrate 1 may be, for example, a single crystalline silicon wafer, a silicon epitaxial layer, or a silicon-on-insulator (SOI) substrate. In some example embodiments, the substrate 1 may be doped with first dopants of a first conductivity type. The first conductivity type may be, for example, a P type, and the first dopants may be or may include for example, boron (B). In some example embodiments, boron may be incorporated into a crystal such as a single-crystal silicon of which the substrate 1 is composed. The substrate 1 may include a front surface 1a and a rear surface 1b, which are opposite to each other. As described herein, the front surface 1a and the rear surface 1b may be referred to as a first surface 1a and a second surface 1b, respectively.

The deep isolation pattern 10 may be disposed in the substrate 1 to separate the large and small light-receiving regions LR and SR of a plurality of pixels PX(1) to PX(3). Each of the pixels PX(1) to PX(3) may have the same or substantially the same layout as described with reference to FIG. 2; example embodiments are not limited thereto. Each of the pixels PX(1) to PX(3) may include the large light-receiving region LR and the small light-receiving region SR. The deep isolation pattern 10 may be interposed between the large and small light-receiving regions LR and SR.

The deep isolation pattern 10 may be placed in a deep trench, which is formed from the front surface 1a of the substrate 1 toward the rear surface 1b. The deep isolation pattern 10 may have a decreasing or tapered width as it extends from the front surface 1a toward the rear surface 1b of the substrate 1. The deep isolation pattern 10 may include a gapfill insulating pattern 16, an isolation insulating pattern 12, and an isolation conductive pattern 14. The gapfill insulating pattern 16 may be interposed between the isolation conductive pattern 14 and a first interlayer insulating layer ILL. The isolation insulating pattern 12 may be interposed between the isolation conductive pattern 14 and the substrate 1 and between the gapfill insulating pattern 16 and the substrate 1. The isolation conductive pattern 14 may include at least one of doped polysilicon or metallic materials. A negative bias or negative voltage may be applied to the isolation conductive pattern 14. The isolation conductive pattern 14 may serve as a common bias line. Accordingly, it may be possible to suppress or reduce a dark current issue and/or a white spot issue in the image sensor.

In the large light-receiving region LR, a large photoelectric conversion part LPD may be disposed in the substrate 1. In the small light-receiving region SR, a small photoelectric conversion part SPD may be disposed in the substrate 1. When viewed in a plan view, an area of the large photoelectric conversion part LPD may be larger than an area of the small photoelectric conversion part SPD. The large photoelectric conversion part LPD and the small photoelectric conversion part SPD may be doped with second dopants, which have a second conductivity type different from the first conductivity type. The second conductivity type may be, for example, an n type, and the second dopants may be or include one or more of arsenic or phosphorus.

A well region PW may be disposed between the large photoelectric conversion part LPD and the first surface 1a and between the small photoelectric conversion part SPD and the first surface 1a, in the substrate 1. The well region PW may be doped with the first dopants of the first conductivity type. A concentration of the first dopant in the well region PW may be higher than, e.g., higher by one or more orders of magnitude than, a concentration of the first dopant in the substrate 1.

In each of the large and small light-receiving regions LR and SR, a shallow isolation pattern 20 may be disposed in the front surface 1a of the substrate 1 to confine active portions ACT. Transistors may be disposed on the active portions ACT.

Referring to FIGS. 3A and 4A, each of the pixels PX(1)-PX(3) may further include transistors TX1, TX2, WX1, WX2, RX, CX, FX and SX and a capacitor CP. In the large light-receiving region LR, a large transfer gate electrode LTG may be disposed on one of the active portions ACT. In some example embodiments, a pair of the large transfer gate electrodes LTG may be provided to be adjacent to each other. Portions of the large transfer gate electrodes LTG may be inserted into the substrate 1. A large floating diffusion region FD_H(1) may be disposed in the substrate 1 and adjacent or near to the large transfer gate electrode LTG. The large floating diffusion region FD_H(1) may be referred to as a dopant region and/or as a large floating diffusion node. The large floating diffusion region FD_H(1) may be doped with the second dopants of the second conductivity type. The large transfer gate electrode LTG and the large floating diffusion region FD_H(1) may constitute (or be included in) a large transfer transistor TX1. The large transfer transistor TX1 may be disposed to be adjacent to a center of the large light-receiving region LR; example embodiments are not limited thereto.

Referring to FIGS. 3A and 4A, in the large light-receiving region LR, a reset gate electrode RG may be disposed on another of the active portions ACT, and a reset dopant region FD_L(3) may be disposed in the substrate 1 at a side of the reset gate electrode RG. The reset dopant region FD_L(3) may be doped with the second dopants of the second conductivity type, e.g., one or both of phosphorus and arsenic. The reset gate electrode RG and the reset dopant region FD_L(3) may constitute or be included in a reset transistor RX. The large transfer gate electrode LTG may be spaced apart from the reset gate electrode RG in a third direction.

Referring to FIGS. 3A and 4A, in the large light-receiving region LR, a dual conversion gain gate electrode DC may be disposed on a different one of the active portions ACT, a first DC dopant region FD_L(1) may be disposed in the substrate 1 at a side of the dual conversion gain gate electrode DC, and a second DC dopant region FD_H(2) may be disposed in the substrate 1 at a side of the dual conversion gain gate electrode DC. The first DC dopant region FD_L(1) and the second DC dopant region FD_H(2) may be doped with the second dopants of the second conductivity type, e.g., one or both of phosphorus and arsenic. The dual conversion gain gate electrode DC, the first DC dopant region FD_L(1), and the second DC dopant region FD_H(2) may constitute or be included in a dual conversion gain transistor CX. The large floating diffusion region FD_H(1) may be spaced apart from the dual conversion gain gate electrode DC in the second direction D2. The large floating diffusion region FD_H(1) and the second DC dopant region FD_H(2) may be connected to each other to serve as the first charge detection node FD_H of FIG. 4A.

Referring to FIGS. 3A and 4A, in the large light-receiving region LR, a selection gate electrode SEL and a source follower gate electrode SF may be disposed, side by side in a direction such as in the third direction D3, on another of the active portions ACT. Dopant regions may be disposed in the substrate 1 at both sides of the selection gate electrode SEL and the source follower gate electrode SF. The selection gate electrode SEL and the dopant regions adjacent thereto may constitute or be included in a selection transistor SX. The source follower gate electrode SF and the dopant regions adjacent thereto may constitute or be included in a source follower transistor FX.

Referring to FIGS. 3A and 4A, in the large light-receiving region LR, a first switch gate electrode SW1 may be disposed on even another of the active portions ACT, and a first SW1 dopant region FD_S(1) and a second SW1 dopant region FD_L(2) may be disposed in the substrate 1 at both sides of first switch gate electrode SW1. The first SW1 dopant region FD_S(1) and the second SW1 dopant region FD_L(2) may be doped with the second dopants of the second conductivity type. The first switch gate electrode SW1, the first SW1 dopant region FD_S(1), and the second SW1 dopant region FD_L(2) may constitute (or be included in) a first switch transistor WX1. The first DC dopant region FD_L(1), the second SW1 dopant region FD_L(2), and the reset dopant region FD_L(3) may be connected to each other to serve as the second charge detection node FD_L of FIG. 4A. The first switch gate electrode SW1 may be spaced apart from the large transfer gate electrode LTG in the first direction D1 and may be adjacent to the small light-receiving region SR.

Referring to FIGS. 3A and 4A, in the small light-receiving region SR, a small transfer gate electrode STG and a second switch gate electrode SW2 may be disposed on one of the active portions ACT. In some example embodiments, a plurality of small transfer gate electrodes STG may be provided. The small transfer gate electrodes STG may be spaced apart from each other in a fourth direction D4. Portions of the small transfer gate electrodes STG may be inserted into the substrate 1. Between the second switch gate electrode SW2 and the small transfer gate electrodes STG, the small floating diffusion region FD_S(2) may be disposed in the substrate 1. The small floating diffusion region FD_S(2) may be referred to as a dopant region. The small transfer gate electrodes STG and the small floating diffusion region FD_S(2) may constitute (or be included in) a small transfer transistor TX2.

The small floating diffusion region FD_S(2) may be doped with the second dopants of the second conductivity type, e.g., one or more of arsenic or phosphorus. The small floating diffusion region FD_S(2) and the first SW1 dopant region FD_S(1) may be electrically connected to each other by a first contact plug CT1, a second contact plug CT2, and a third node connection line FD_SL. The small floating diffusion region FD_S(2) and the first SW1 dopant region FD_S(1) may serve as the third charge detection node FD_S of FIG. 4A.

A fourth charge detection node FD_CP, which is a dopant region doped with the second dopants, may be disposed in the substrate 1 at an opposite side of the second switch gate electrode SW2. The second switch gate electrode SW2 and the fourth charge detection node FD_CP may constitute (or be included in) a second switch transistor WX2. A capacitor CP may be connected to the fourth charge detection node FD_CP. The capacitor CP may be or may include, for example, a metal-insulator-metal (MIM) type capacitor, a concave embedded capacitor, and/or a one cylinder stacked (OCS) capacitor of a dynamic random access memory (DRAM) device.

Each of, or at least some of, the transistors included in the large light-receiving region LR and/or the small light-receiving region SR may have the same, or different, physical and/or electrical characteristics. For example, there may be the same or different oxide thicknesses and/or gate widths and/or gate lengths among the transistors included in the large light-receiving region LR and/or the small light-receiving region SR. Alternatively or additionally there may be the same or different threshold voltages and/or drive currents among the transistors included in the among the transistors included in the large light-receiving region LR and/or the small light-receiving region SR. Example embodiments are not limited thereto.

In the large light-receiving region LR, a first ground region GN1 may be disposed in still another of the active portions ACT. In the small light-receiving region SR, a second ground region GN2 may be disposed in another of the active portions ACT. The first and second ground regions GN1 and GN2 may be doped with the first dopants of the first conductivity type, such as but not limited to boron. Concentrations of the first dopant in the first and second ground regions GN1 and GN2 may be higher than, e.g., higher by one or more orders of magnitude than, a concentration of the first dopant in the substrate 1.

Referring to FIG. 3B, the well region PW may be disposed between the large floating diffusion region FD_H(1) and the large photoelectric conversion part LPD and between the first SW1 dopant region FD_S(1) and the large photoelectric conversion part LPD. In addition, the well region PW may be disposed between the small floating diffusion region FD_S(2) and the small photoelectric conversion part SPD. A concentration of the second dopant in the large photoelectric conversion part LPD may be different from, e.g., less than or greater than, e.g., by one or more orders of magnitude than, a concentration of the second dopant in the small photoelectric conversion part SPD. In some example embodiments, the concentration of the second dopant in the large photoelectric conversion part LPD may be higher than the concentration of the second dopant in the small photoelectric conversion part SPD, e.g., by one or more orders of magnitude.

The reset gate electrode RG, the dual conversion gain gate electrode DC, the selection gate electrode SEL, the source follower gate electrode SF, the first switch gate electrode SW1, and the second switch gate electrode SW2 may be of a planar type and may be placed on the front surface 1a of the substrate 1; example embodiments, however, are not limited thereto. A gate insulating layer Gox may be interposed between the substrate 1 and the large transfer gate electrodes LTG, the small transfer gate electrodes STG, the reset gate electrode RG, the dual conversion gain gate electrode DC, the selection gate electrode SEL, the source follower gate electrode SF, the first switch gate electrode SW1, and the second switch gate electrode SW2. The gate insulating layer Gox may be formed of or include at least one of silicon oxide and/or metal oxide.

The front surface 1a of the substrate 1 may be sequentially covered with first to third interlayer insulating layers IL1 to IL3. Each of the first to third interlayer insulating layers IL1 to IL3 may be formed of or include at least one of silicon oxide, silicon nitride, silicon oxynitride, porous insulating materials and may have a single- or multi-layered structure. The third node connection line FD_SL and first interconnection lines M1 may be disposed between the first interlayer insulating layer IL1 and a second interlayer insulating layer IL2. Second interconnection lines M2 may be disposed between the second interlayer insulating layer IL2 and the third interlayer insulating layer IL3.

The rear surface 1b of the substrate 1 may be sequentially covered with a fixed charge layer 24 and an anti-reflection layer 42. The fixed charge layer 24 may be in contact with the rear surface 1b. The fixed charge layer 24 may have a negative fixed charge. The fixed charge layer 24 may be formed of metal oxide or metal fluoride containing at least one metal, which is selected from the group consisting of or including hafnium (Hf), zirconium (Zr), aluminum (Al), tantalum (Ta), titanium (Ti), yttrium (Y), and lanthanoid. For example, the fixed charge layer 24 may be a hafnium oxide layer and/or an aluminum oxide layer. Here, a hole accumulation may occur near the fixed charge layer 24. Accordingly, it may be possible to effectively reduce or suppress a dark current issue and/or a white spot issue.

The anti-reflection layer 42 may be formed of or include at least one of titanium oxide, silicon nitride, silicon oxide, or hafnium oxide and may have a single- or multi-layered structure.

A first grid pattern 48a and a second grid pattern 50a may be sequentially formed on the anti-reflection layer 42. The first grid pattern 48a and the second grid pattern 50a may have a mesh or net shape, when viewed in a plan view. The first grid pattern 48a and the second grid pattern 50a may be provided to expose the anti-reflection layer 42.

The first grid pattern 48a may include an optically opaque material (e.g., titanium). A side surface of the second grid pattern 50a may be aligned to a side surface of the first grid pattern 48a. The first grid pattern 48a and the second grid pattern 50a may prevent or reduce the likelihood of and/or impact from a cross-talk issue from occurring between adjacent ones of the pixels. The second grid pattern 50a may include an organic material. The second grid pattern 50a may have a refractive index that is smaller than the color filters CF1, CF2, and CF3. For example, the second grid pattern 50a may have a refractive index of about 1.3 or lower.

The color filters CF1, CF2, and CF3 may be disposed below the anti-reflection layer 42. FIG. 3B illustrates an example of the first color filter CF1. The first and second micro lenses ML1 and ML2 may be disposed below the color filters CF1, CF2, and CF3. The first micro lens ML1 may be overlapped with the large light-receiving region LR. The second micro lens ML2 may be overlapped with the small light-receiving region SR.

Referring to FIGS. 3A, 3B, 4A, and 4B, in an operation of the image sensor, a reset signal S_S_RG and a dual conversion gain signal S_DC may first be activated to turn on the reset transistor RX and the dual conversion gain transistor CX. Thus, a pixel power voltage VPIX may be provided to the first charge detection node FD_H to discharge electric charges from the first and second charge detection nodes FD_H and FD_L, and thus, the first and second charge detection nodes FD_H and FD_L may be reset or initialized. Meanwhile, when the reset signal S_RG is activated, a first switch signal S_SW1 may be activated to reset the third charge detection node FD_S.

Next, the reset signal S_RG and the dual conversion gain signal S_DC may be inactivated to turn off the reset transistor RX and the dual conversion gain transistor CX. Accordingly, the first, second, and third charge detection nodes FD_H, FD_L, and FD_S may be in a state where charge accumulation is possible.

After, e.g., immediately after the reset transistor RX and the dual conversion gain transistor CX are turned off, a selection signal S_SEL may be activated to turn on the selection transistor SX. If the selection transistor SX is turned on, pixel signals may be output through an output line Vout.

At time t0, a first reset signal proportional to an electric potential in the first charge detection node FD_H may be output.

After the readout of the first reset signal, a first transfer signal S_LTG may be activated to turn on the large transfer transistor TX1. Thus, in a first conversion gain mode, electric charges accumulated in the large photoelectric conversion part LPD may be transferred to the first charge detection node FD_H.

Next, the first transfer signal S_LTG may be inactivated to turn off the large transfer transistor TX1, and at time t1, a first pixel signal may be output in proportion to an amount of photocharges, e.g., electrons or holes, which are accumulated in the large photoelectric conversion part LPD in the first conversion gain mode.

After the output of the first pixel signal, the dual conversion gain signal S_DC may be activated to turn on the dual conversion gain transistor CX. Thus, the unit pixel PX may be operated in a second conversion gain mode having a second conversion gain greater than the first conversion gain. Since the dual conversion gain transistor CX is turned on, an electrostatic capacitance of the first charge detection node FD_H may be increased to a sum of electrostatic capacitances of the first and second charge detection nodes FD_H and FD_L, e.g., based on a parallel capacitance.

After turning on the dual conversion gain transistor CX, at time t2, a second reset signal proportional to the electric potential of the first and second charge detection nodes FD_H and FD_L may be output.

After the readout of the second reset signal, the first transfer signal S_LTG may be activated to turn on the large transfer transistor TX1 again. Thus, electric charges, which are accumulated in the large photoelectric conversion part LPD in the second conversion gain mode, may be transferred to the first and second charge detection nodes FD_H and FD_L.

Next, the first transfer signal S_LTG may be inactivated to turn off the large transfer transistor TX1, and at time t3, a second pixel signal may be output in proportion to an amount of photocharges, which are accumulated in the large photoelectric conversion part LPD in the second conversion gain mode. For example, the second pixel signal may be proportional to an amount of charges accumulated in the first and second charge detection nodes FD_H and FD_L.

Next, the reset signal S_RG may be re-activated to turn on the reset transistor RX. Thus, electric charges may be discharged from the first and second charge detection nodes FD_H and FD_L, and the first and second charge detection nodes FD_H and FD_L may be reset.

After the reset of the first and second charge detection nodes FD_H and FD_L, the first switch signal S_SW1 may be activated to turn on the first switch transistor WX1. Thus, the unit pixel PX may be operated in a third conversion gain mode, in which the unit pixel PX has a third conversion gain greater than the second conversion gain.

Since the first switch transistor WX1 and the dual conversion gain transistor CX are turned on, an electrostatic capacitance of the first charge detection node FD_H may be increased to a sum of electrostatic capacitances of the first, second, and third charge detection nodes FD_H, FD_L, and FD_S, e.g., based on a parallel connection therebetween. After turning on the first switch transistor WX1, at time t4, a third reset signal may be output in proportion to the electric potential of the first, second and third charge detection nodes FD_H, FD_L, and FD_S.

After the readout of the third reset signal, a second transfer signal S_STG may be activated to turn on the small transfer transistor TX2. Thus, electric charges, which are accumulated in the small photoelectric conversion part SPD in the third conversion gain mode, may be transferred to the first, second, and third charge detection nodes FD_H, FD_L, and FD_S.

Next, the second transfer signal S_STG may be inactivated to turnoff the small transfer transistor TX2, and at time t5, a third pixel signal may be output in proportion to an amount of photocharges, which are accumulated in the small photoelectric conversion part SPD. In other words, the third pixel signal may be proportional to an amount of charges, which are stored in the first, second, and third charge detection nodes FD_H, FD_L, and FD_S.

After the output of the third pixel signal, a second switch signal S_SW2 may be activated to turn on the second switch transistor WX2. Thus, the unit pixel PX may be operated in a fourth conversion gain mode having a fourth conversion gain greater than the third conversion gain. Since the second switch transistor WX2 is turned on, an electrostatic capacitance of the first charge detection node FD_H may be increased to a sum of electrostatic capacitances of the first, second, and third charge detection nodes FD_H, FD_L, and FD_S and the capacitor CP, e.g., based on a parallel connection therebetween.

After turning on the second switch transistor WX2, at time t6, a fourth reset signal may be output in proportion to an electric potential of the first, second, third and fourth charge detection nodes FD_H, FD_L, FD_S, and FD_CP.

After the readout of the fourth reset signal, the second transfer signal S_STG may be re-activated to turn on the small transfer transistor TX2. Thus, electric charges, which are accumulated in the small photoelectric conversion part SPD in the fourth conversion gain mode, may be transferred to the first, second, third and fourth charge detection nodes FD_H, FD_L, FD_S, and FD_CP.

Next, the second transfer signal S_STG may be inactivated to turnoff the small transfer transistor TX2, and at time t7, a fourth pixel signal may be output in proportion to an amount of photocharges, which are accumulated in the small photoelectric conversion part SPD in the fourth conversion gain mode. For example, the fourth pixel signal may be proportional to an amount of charges, which are stored in the first, second, third and fourth charge detection nodes FD_H, FD_L, FD_S, and FD_CP, e.g., based on a parallel connection therebetween.

The length of time between each of times t1 to t7 maybe be variable, and FIG. 4B is an example. For example, the length of time between time t1 and t2 may be the same as, or different than (greater than or less than) the length of time between time t2 and time t3. Example embodiments are not limited thereto.

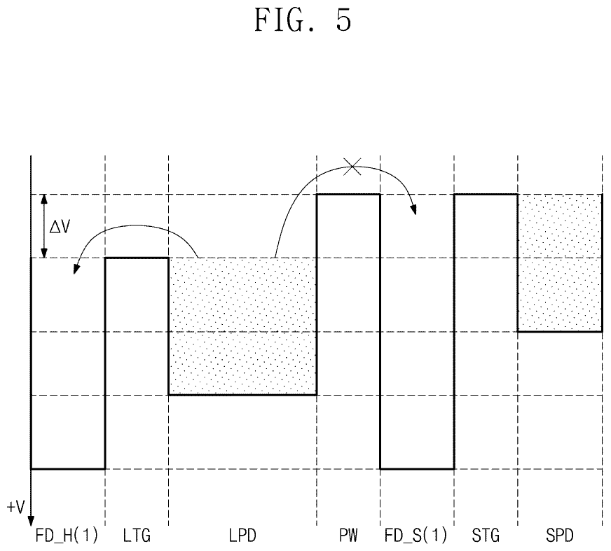

FIG. 5 is a potential diagram of the image sensor of FIGS. 3A and 3B.

Referring to FIGS. 3A, 3B, 4A, 4B, and 5, in an optical integration mode of the small photoelectric conversion part SPD, the small transfer transistor TX2 may be turned on to transfer and store electric charges, which are generated in the small photoelectric conversion part SPD, to the small floating diffusion region FD_S(2).

If a pixel signal is output in proportion to an amount of photocharges accumulated in the small photoelectric conversion part SPD, electric charges, which are generated in the large photoelectric conversion part LPD by high intensity light incident into the image sensor, may overflow to the first SW1 dopant region FD_S(1) beyond a potential barrier in the well region PW. The overflown photocharges may be transferred to the small floating diffusion region FD_S(2) through the third node connection line FD_SL. In this case, there may be a blooming phenomenon, which may distort the pixel signal output from the small photoelectric conversion part SPD.

However, in the image sensor according to some example embodiments, since a concentration of the second dopant in the large photoelectric conversion part LPD is greater than a concentration of the second dopant in the small photoelectric conversion part SPD, an electrostatic potential of the large transfer gate electrode LTG may be lowered by a potential difference ΔV, as compared with an electric potential of the well region PW, and a shut off potential may be lowered. The large transfer gate electrode LTG may be in a low shut off state. Thus, electric charges, which are generated in the large photoelectric conversion part LPD, may be transferred to the large floating diffusion region FD_H(1), and not to or mostly not to the first SW1 dopant region FD_S(1). Thus, it may be possible to prevent or reduce an impact from and/or an occurrence of a blooming phenomenon from the large light-receiving region LR to the small light-receiving region SR and thereby to realize a clear image or a clearer image.

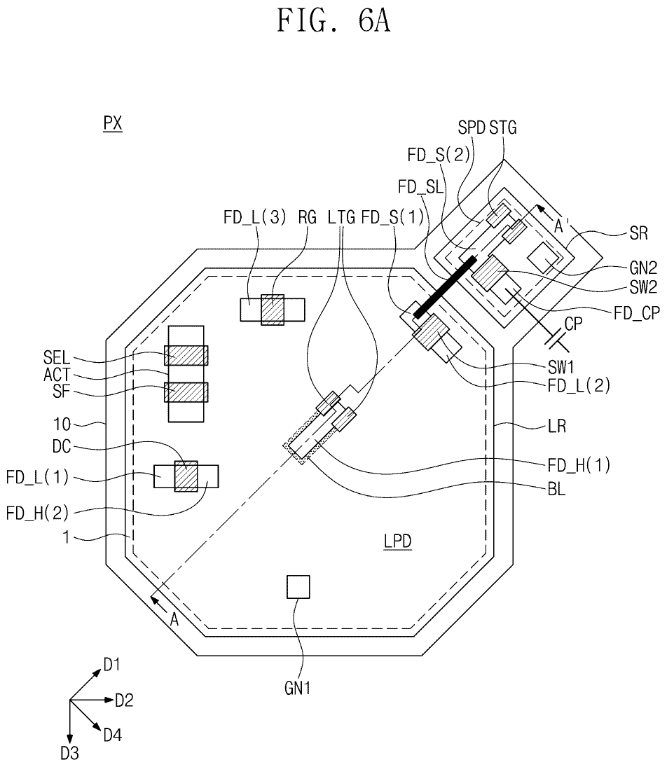

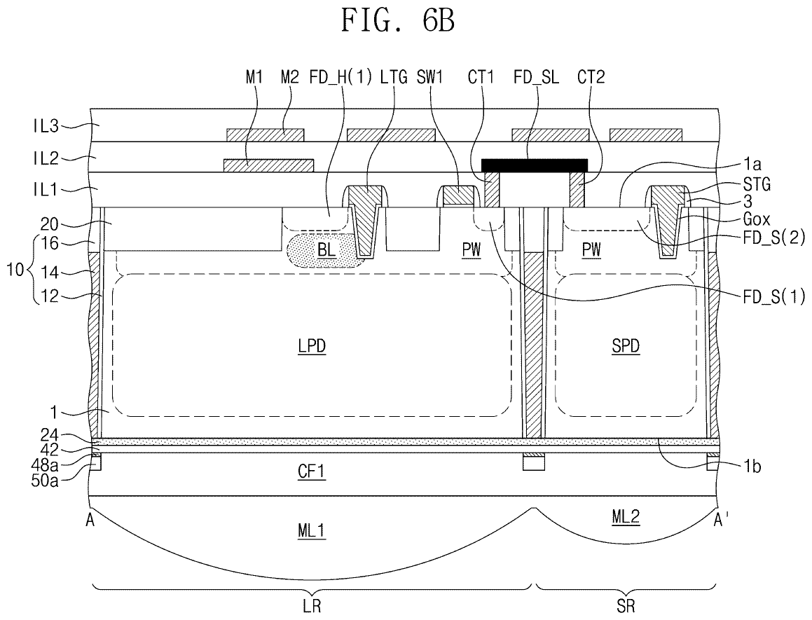

FIG. 6A is a layout illustrating an image sensor according to some example embodiments. FIG. 6B is a sectional view taken along a line A-A′ of FIG. 6A. The layout of FIG. 6A may correspond to one pixel PX of the pixel array of FIG. 2.

Referring to FIGS. 5, 6A, and 6B, in the image sensor in some example embodiments, a concentration of the second dopant in the large photoelectric conversion part LPD may be equal to or substantially equal to a concentration of the second dopant in the small photoelectric conversion part SPD. A buried region BL may be disposed in the large light-receiving region LR and between the large photoelectric conversion part LPD and the large floating diffusion region FD_H(1). The buried region BL may be doped with the first dopants of the first conductivity type, which are the same as those doped in the well region PW. A concentration of the first dopant in the buried region BL may be lower than, e.g., lower by an order of magnitude or more than, a concentration of the first dopant in the well region PW. Additionally or alternatively, the buried region BL may further contain the second dopants of the second conductivity type, which are the same as those doped in the large floating diffusion region FD_H(1). Thus, an electrostatic potential of the large transfer gate electrode LTG may be lowered by the buried region BL, and a shut off potential may be lowered. The large transfer gate electrode LTG may be in a low shut off state. Accordingly, electric charges, which are generated in the large photoelectric conversion part LPD, may be transferred to the large floating diffusion region FD_H(1), not to or mostly not to the first SW1 dopant region FD_S(1). Thus, it may be possible to prevent or reduce the likelihood of and/or the impact from a blooming phenomenon from the large light-receiving region LR to the small light-receiving region SR and thereby to realize a clear image. Except for the afore-described differences, the image sensor may have the same or substantially the same features as that described with reference to FIGS. 2 to 5.

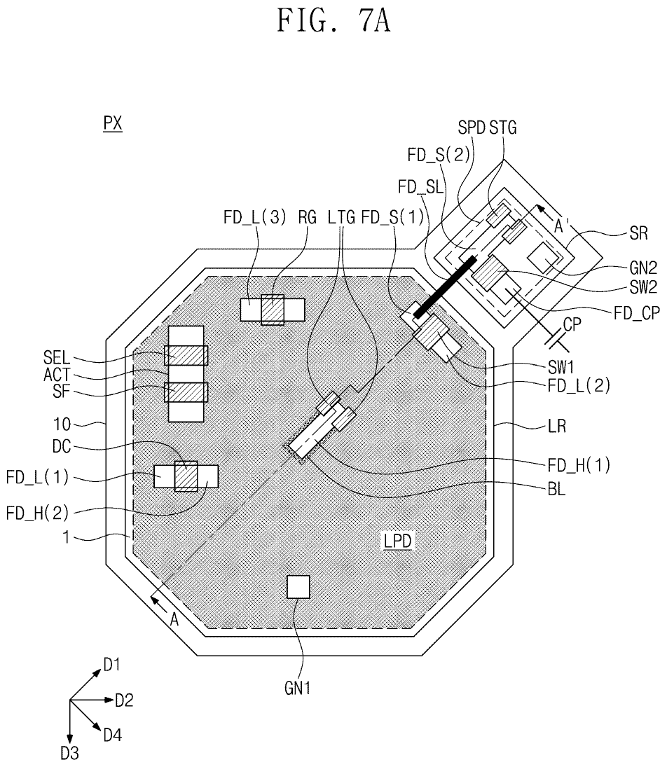

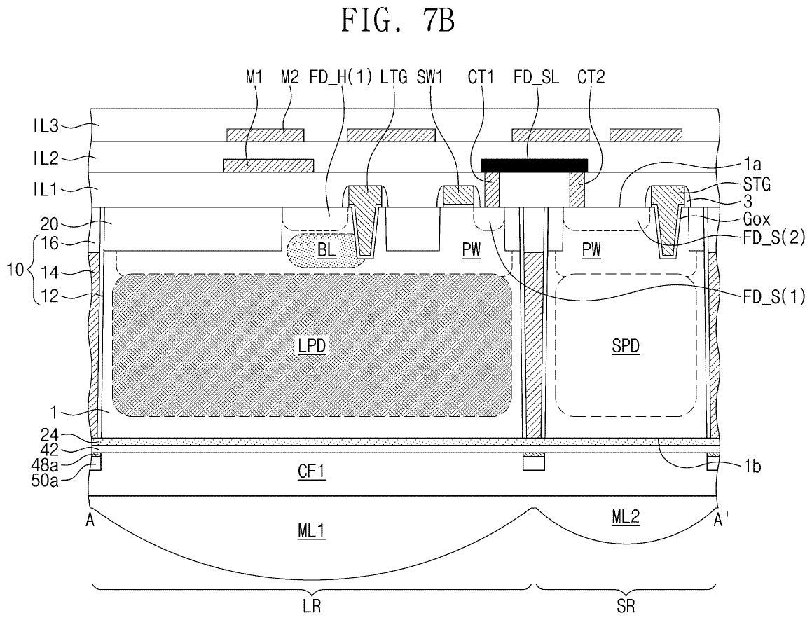

FIG. 7A is a layout illustrating an image sensor according to some example embodiments. FIG. 7B is a sectional view taken along a line A-A′ of FIG. 7A. The layout of FIG. 7A may correspond to one pixel PX of the pixel array of FIG. 2.

Referring to FIGS. 5, 7A, and 7B, in the image sensor in some example embodiments, a concentration of the second dopant in the large photoelectric conversion part LPD may be higher than, e.g., higher by an order of magnitude or more than, a concentration of the second dopant in the small photoelectric conversion part SPD. The buried region BL may be disposed between the large photoelectric conversion part LPD and the large floating diffusion region FD_H(1). A concentration of the first dopant in the buried region BL may be lower than, e.g., lower by an order of magnitude or more than, a concentration of the first dopant in the well region PW. Additionally or alternatively, the buried region BL may further contain the second dopants of the second conductivity type, which are the same as those doped in the large floating diffusion region FD_H(1). Accordingly, an electrostatic potential of the large transfer gate electrode LTG may be lowered by the buried region BL. Except for the afore-described differences, the image sensor may have substantially the same features as that described with reference to FIGS. 2 to 6B.

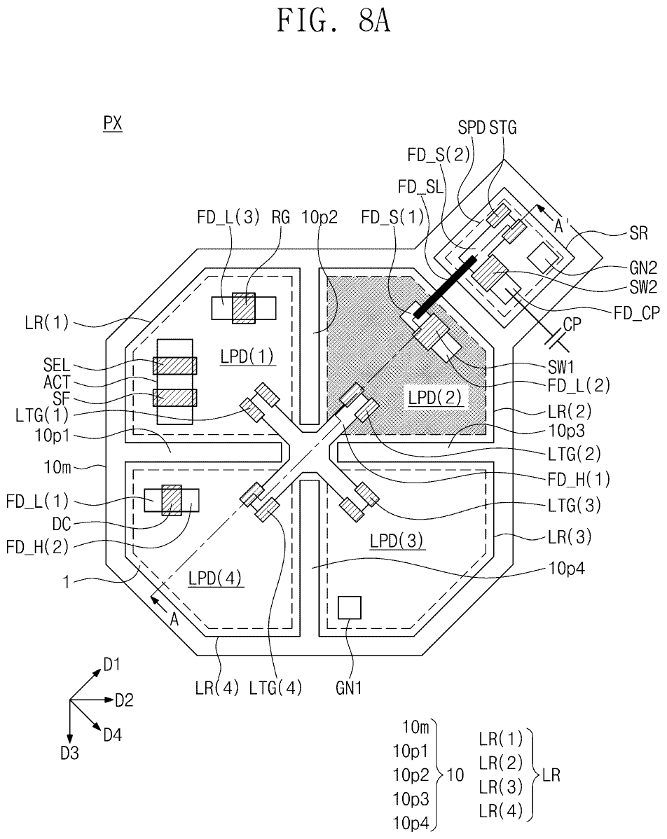

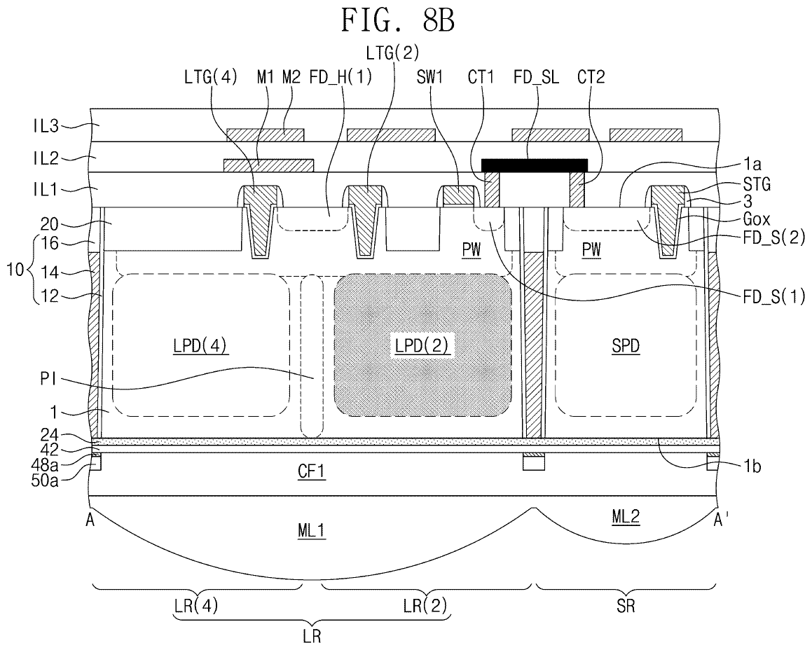

FIG. 8A is a layout illustrating an image sensor according to some example embodiments. FIG. 8B is a sectional view taken along a line A-A′ of FIG. 8A. The layout of FIG. 8A may correspond to one pixel PX of the pixel array of FIG. 2.

Referring to FIGS. 8A and 8B, when viewed in a plan view, the deep isolation pattern 10 may be inserted into the large light-receiving region LR to divide the large light-receiving region LR into four sub-large light-receiving regions LR(1) to LR(4). In detail, the deep isolation pattern 10 may include a main isolation portion 10m and first to fourth insertion isolation portions 10p1 to 10p4. The main isolation portion 10m may enclose each of the large and small light-receiving regions LR and SR. The first to fourth insertion isolation portions 10p1 to 10p4 may be extended from a side surface of the main isolation portion 10m and may be inserted into the large light-receiving region LR. The first to fourth insertion isolation portions 10p1 to 10p4 may be arranged in a clockwise direction. End portions of the first to fourth insertion isolation portions 10p1 to 10p4 may be adjacent to the center of the large light-receiving region LR but may not be connected to each other. The first and third insertion isolation portions 10p1 and 10p3 may be elongated in the second direction D2, and the second and fourth insertion isolation portions 10p2 and 10p4 may be elongated in the third direction D3.

The first to fourth sub-large light-receiving regions LR(1) to LR(4) may be arranged in a clockwise direction. The second sub-large light-receiving region LR(2) may be closer to the small light-receiving region SR than at least one of, or all of, the first, third, and fourth sub-large light-receiving regions LR(1), LR(3), and LR(4). The first to fourth sub-large light-receiving regions LR(1) to LR(4) may be covered with the first micro lens ML1.

The first to fourth sub-large transfer gate electrodes LTG(1) to LTG(4) may be disposed in the first to fourth sub-large light-receiving regions LR(1) to LR(4), respectively. Each of the first to fourth sub-large transfer gate electrodes LTG(1) to LTG(4) may be provided in plural. The large floating diffusion region FD_H(1) may be disposed at a side of each of the first to fourth sub-large transfer gate electrodes LTG(1) to LTG(4). The first to fourth sub-large transfer gate electrodes LTG(1) to LTG(4) and the large floating diffusion regions FD_H(1) may be disposed to be adjacent to the center of the large light-receiving region LR, and the large floating diffusion regions FD_H(1) may be connected to each other to form an ‘X’ shape, when viewed in a plan view.

An isolation region PI may be disposed in the substrate 1 and at the center of the large light-receiving region LR. The isolation region PI may be doped with the first dopants of the first conductivity type, which are the same as those doped in the substrate 1. The concentration of the first dopant in the isolation region PI may be higher than the concentration of the first dopant of the substrate 1. The isolation region PI may be placed below the large floating diffusion regions FD_H(1).

The reset gate electrode RG, the reset dopant region FD_L(3), the selection gate electrode SEL, and the source follower gate electrode SF may be disposed in the first sub-large light-receiving region LR(1). The first switch gate electrode SW1, the first SW1 dopant region FD_S(1), and the second SW1 dopant region FD_L(2) may be disposed in the second sub-large light-receiving region LR(2).

The dual conversion gain gate electrode DC, the first DC dopant region FD_L(1), and the second DC dopant region FD_H(2) may be disposed in the third sub-large light-receiving region LR(3). The first ground region GN1 may be disposed in the fourth sub-large light-receiving region LR(4).

The first to fourth sub-large photoelectric conversion parts LPD(1) to LPD(4) may be disposed in the substrate 1 to correspond to the first to fourth sub-large light-receiving regions LR(1) to LR(4), respectively. The concentration of the second dopant in the second sub-large photoelectric conversion part LPD(2) may be higher than, e.g., higher by an order of magnitude or more than, the concentrations of the second dopant in the first, third, and fourth sub-large photoelectric conversion parts LPD(1), LPD(3), and LPD(4). The concentration of the second dopant in the second sub-large photoelectric conversion part LPD(2) may be higher than, e.g., higher by an order of magnitude or more than, the concentration of the second dopant in the small photoelectric conversion part SPD.

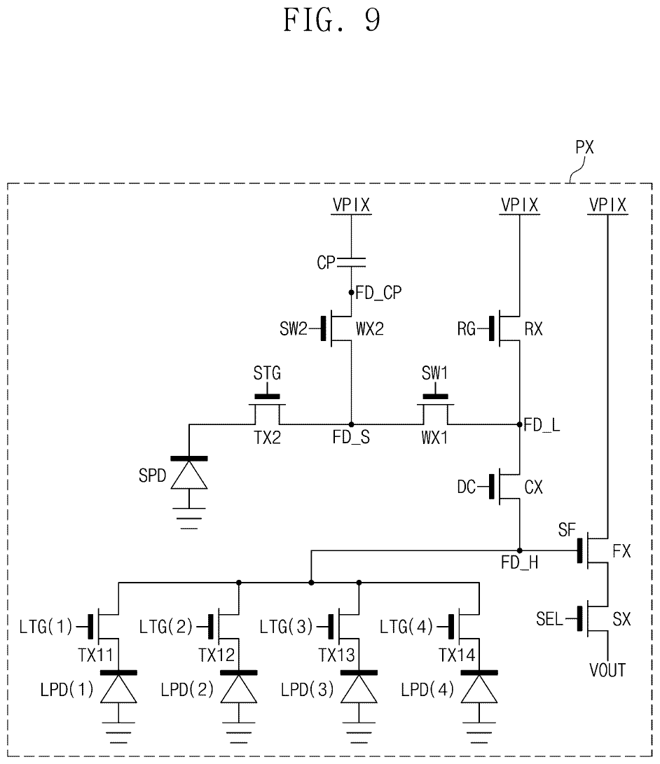

FIG. 9 is a circuit diagram illustrating the image sensor of FIG. 8A.

Referring to FIGS. 8A and 9, a first sub-large transfer gate electrode LTG(1) and the large floating diffusion region FD_H(1), which are adjacent to each other, may constitute an eleventh sub-large transfer transistor TX11. A second sub-large transfer gate electrode LTG(2) and the large floating diffusion region FD_H(1), which are adjacent to each other, may constitute a twelfth sub-large transfer transistor TX12. A third sub-large transfer gate electrode LTG(3) and the large floating diffusion region FD_H(1), which are adjacent to each other, may constitute a thirteenth sub-large transfer transistor TX13. A fourth sub-large transfer gate electrode LTG(4) and the large floating diffusion region FD_H(1), which are adjacent to each other, may constitute a fourteenth sub-large transfer transistor TX14. The unit pixel PX of the image sensor in some example embodiments may have a structure, in which four sub-large transfer transistors TX11 to TX14 are connected to the first charge detection node FD_H in the circuit diagram of FIG. 4A. The sub-large transfer transistors TX11 to TX14 may be simultaneously or sequentially turned on.

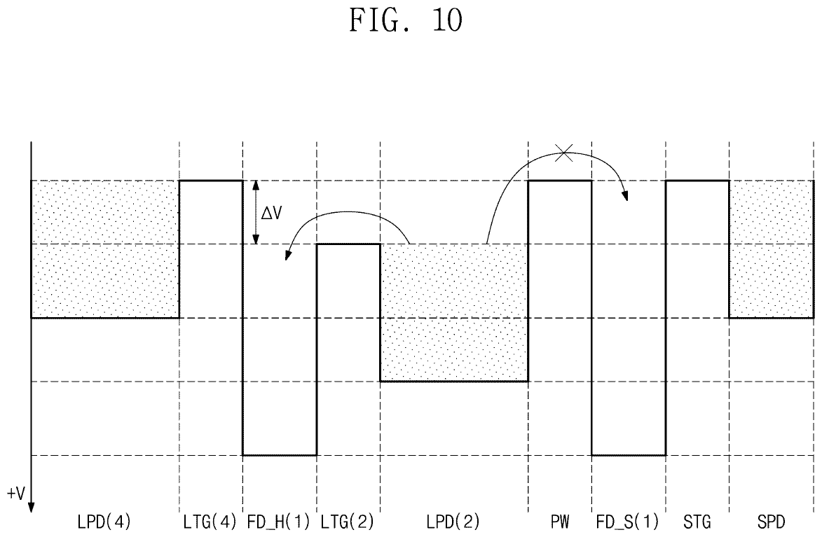

FIG. 10 is a potential diagram of the image sensor of FIGS. 8A and 8B.

Referring to FIGS. 8A to 10, since the concentration of the second dopant in the second sub-large photoelectric conversion part LPD(2) is higher than the concentrations of the second dopant in the first, third, and fourth sub-large photoelectric conversion parts LPD(1), LPD(3), and LPD(4) and the small photoelectric conversion part SPD, an electrostatic potential of the second sub-large transfer gate electrode LTG(2) may be lowered by a potential difference ΔV, compared with a potential in the well region PW, and a shut off potential may be lowered. Since the concentrations of the second dopant in the first, third, and fourth sub-large photoelectric conversion parts LPD(1), LPD(3), and LPD(4) are low, the first, third, and fourth sub-large transfer gate electrodes LTG(1), LTG(3), and LTG(4) of the first, third, and fourth sub-large photoelectric conversion parts LPD(1), LPD(3), and LPD(4) and the small transfer gate electrode STG may have an increased shut off potential. Thus, electric charges, which are generated in the second sub-large photoelectric conversion part LPD(2), may be transferred to the large floating diffusion region FD_H(1), not to the first SW1 dopant region FD_S(1). Accordingly, a blooming phenomenon from the large light-receiving region LR to the small light-receiving region SR may be prevented or reduced in likelihood of occurrence and/or in impact from occurrence. Alternatively or additionally, it may be possible to increase a full well capacity (FWC) in the first, third, and fourth sub-large photoelectric conversion parts LPD(1), LPD(3), and LPD(4) and the small photoelectric conversion part SPD. This may make it possible to realize a clear image.

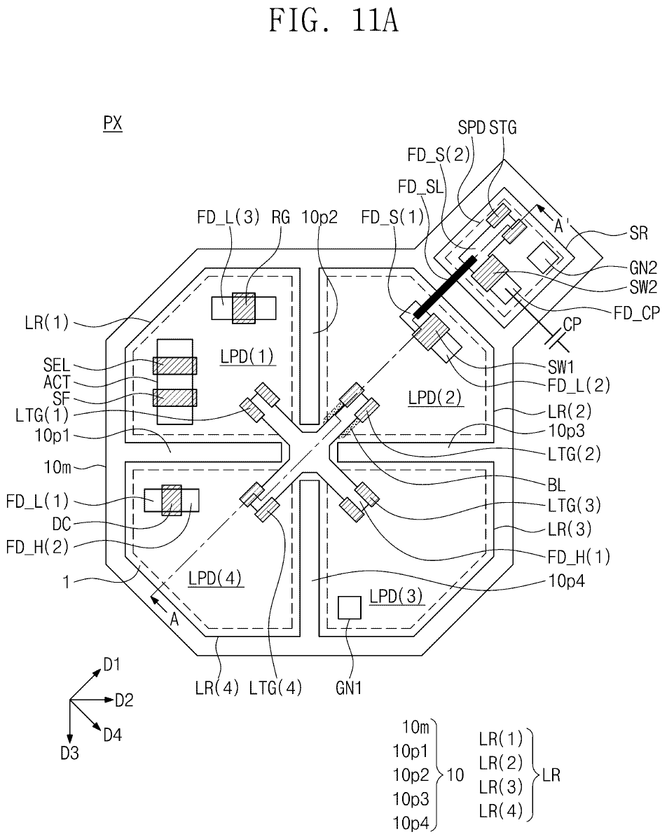

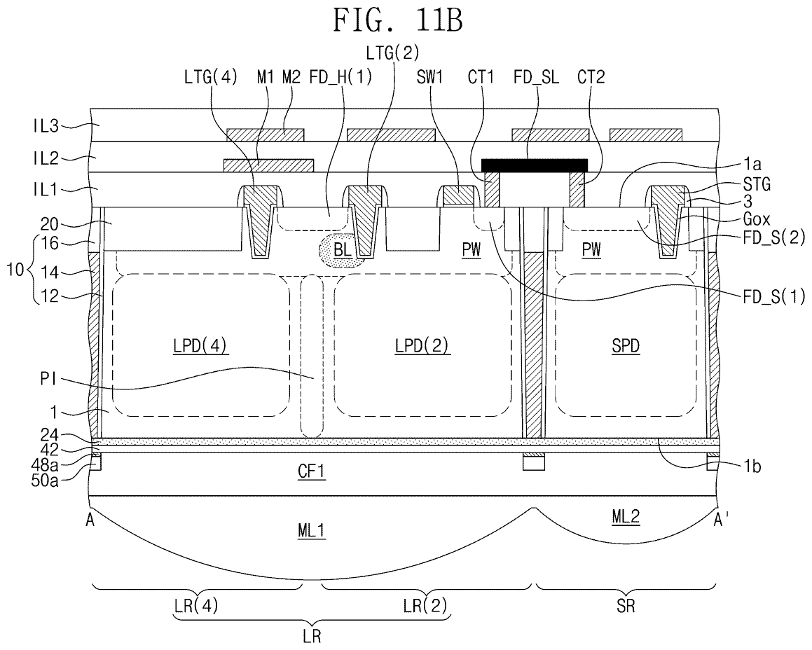

FIG. 11A is a layout illustrating an image sensor according to some example embodiments. FIG. 11B is a sectional view taken along a line A-A′ of FIG. 11A. The layout of FIG. 11A may correspond to one pixel PX of the pixel array of FIG. 2.

Referring to FIGS. 11A and 11B, a concentration of the second dopant in the second sub-large photoelectric conversion part LPD(2) may be substantially equal to concentrations of the second dopant in the first, third, and fourth sub-large photoelectric conversion parts LPD(1), LPD(3), and LPD(4). The concentration of the second dopant in the second sub-large photoelectric conversion part LPD(2) may be equal to the concentration of the second dopant in the small photoelectric conversion part SPD. The buried region BL may be disposed between the large floating diffusion region FD_H(1), which is placed adjacent or near the second sub-large transfer gate electrode LTG(2), and the second sub-large photoelectric conversion part LPD(2). The buried region BL may be doped with the first dopants of the first conductivity type, which are the same as those doped in the well region PW. The concentration of the first dopant in the buried region BL may be lower than the concentration of the first dopant in the well region PW. Additionally or alternatively, the buried region BL may further contain the second dopants of the second conductivity type, which are the same as those doped in the large floating diffusion region FD_H(1). Accordingly, due to the buried region BL, the electrostatic potential of the second sub-large transfer gate electrode LTG(2) may be lowered by a potential difference ΔV, compared with an electric potential in the well region PW, and a shut off potential may be lowered. Except for the afore-described differences, the image sensor may have substantially the same features as that described with reference to FIGS. 8A to 10.

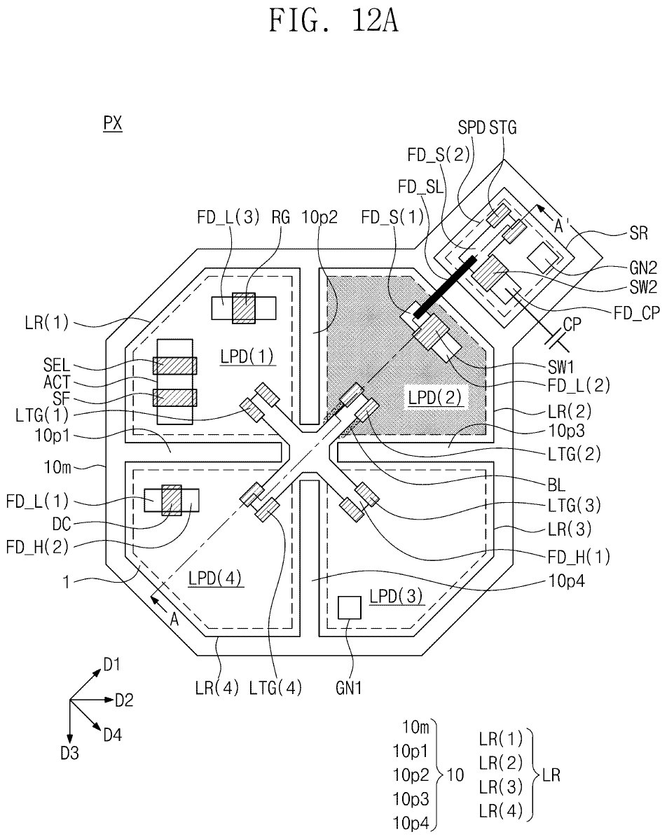

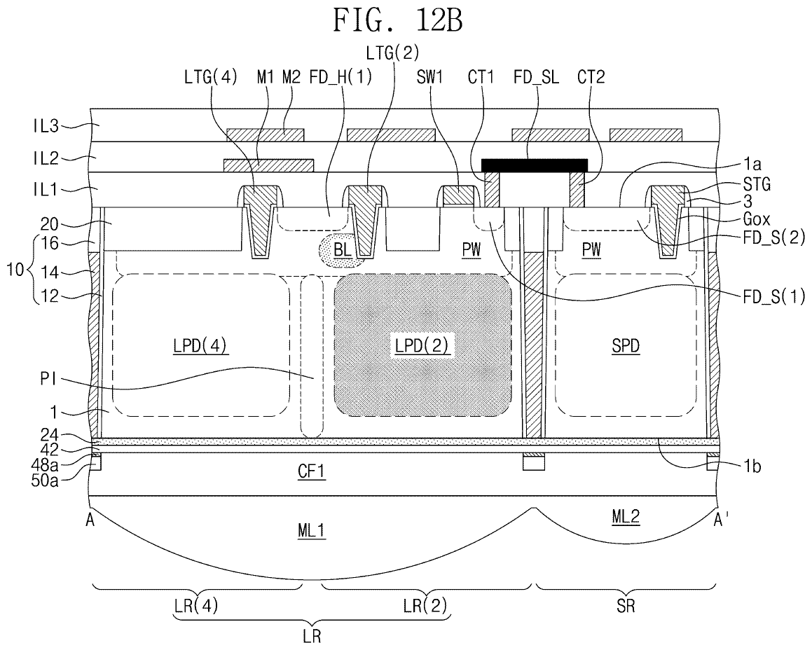

FIG. 12A is a layout illustrating an image sensor according to some example embodiments. FIG. 12B is a sectional view taken along a line A-A′ of FIG. 12A. The layout of FIG. 12A may correspond to one pixel PX of the pixel array of FIG. 2.

Referring to FIGS. 12A and 12B, a concentration of the second dopant in the second sub-large photoelectric conversion part LPD(2) may be higher than concentrations of the second dopant in the first, third, and fourth sub-large photoelectric conversion parts LPD(1), LPD(3), and LPD(4). The concentration of the second dopant in the second sub-large photoelectric conversion part LPD(2) may be higher than the concentration of the second dopant in the small photoelectric conversion part SPD. The buried region BL may be disposed between the large floating diffusion region FD_H(1), which is placed adjacent or near the second sub-large transfer gate electrode LTG(2), and the second sub-large photoelectric conversion part LPD(2). Except the above features, the image sensor according to the present example embodiments may be the same or substantially the same as those in other example embodiments described with reference to FIGS. 11A and 11B.

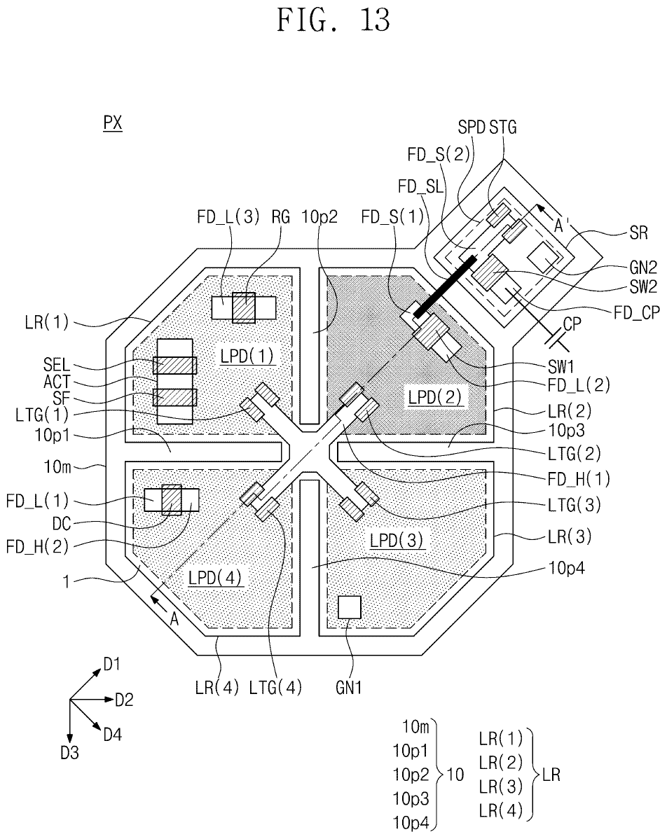

FIG. 13 is a layout illustrating an image sensor according to some example embodiments. A section taken along a line A-A′ of FIG. 13 may be similar to FIG. 8B. The layout of FIG. 13 may correspond to one pixel PX of the pixel array of FIG. 2.

Referring to FIG. 13, in the image sensor in some example embodiments, the concentrations of the second dopant in the first, third, and fourth sub-large photoelectric conversion parts LPD(1), LPD(3), and LPD(4) may be lower than the concentration of the second dopant in the second sub-large photoelectric conversion part LPD(2) and may be higher than the concentration of the second dopant in the small photoelectric conversion part SPD. For example, the concentration of the second dopant may be highest, e.g., highest by an order of magnitude or more, in the second sub-large photoelectric conversion part LPD(2) and lowest, e.g., lowest by an order of magnitude or more, in the small photoelectric conversion part SPD. Accordingly, it may be possible to increase the FWC and to suppress or at least partially suppress the blooming phenomenon. Except the above features, the image sensor according to the present example embodiments may be the same or substantially the same as those in other example embodiments described with reference to FIGS. 8A and 8B; example embodiments are not limited thereto.

FIG. 14 is a layout illustrating an image sensor according to some example embodiments. A section taken along a line A-A′ of FIG. 14 may be similar to FIG. 8B. The layout of FIG. 14 may correspond to one pixel PX of the pixel array of FIG. 2.

Referring to FIG. 14, in the image sensor in some example embodiments, concentrations of the second dopant in the first to fourth sub-large photoelectric conversion parts LPD(1) to LPD(4) may be equal to each other and may be higher than a concentration of the second dopant in the small photoelectric conversion part SPD. Accordingly, it may be possible to increase the FWC and to suppress the blooming phenomenon. Except the above features, the image sensor according to the present example embodiments may be substantially the same as those in other example embodiments described with reference to FIGS. 8A and 8B.

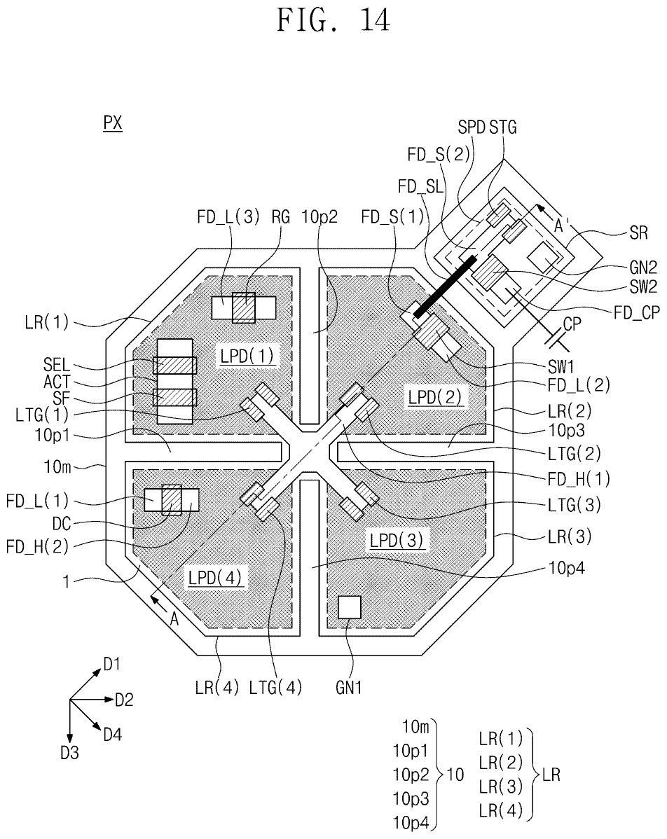

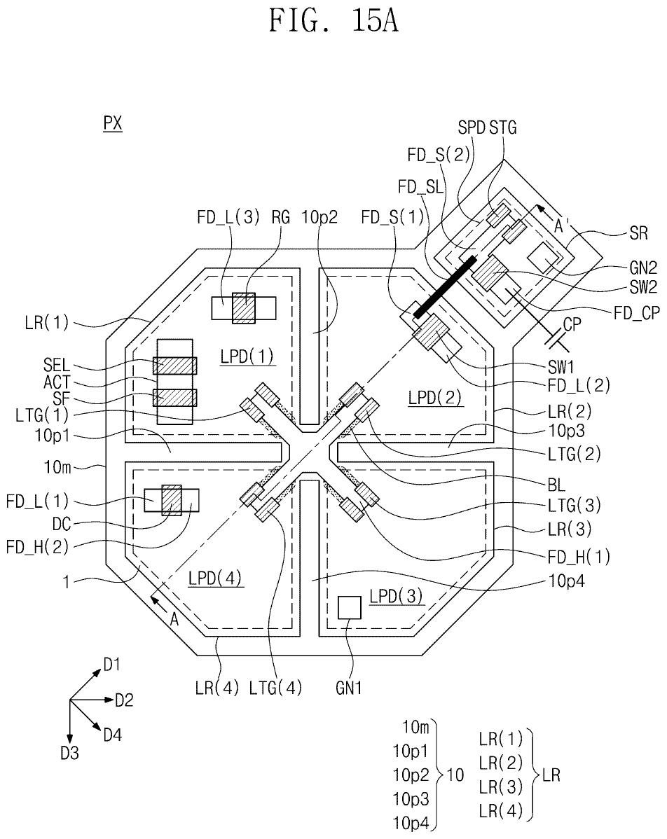

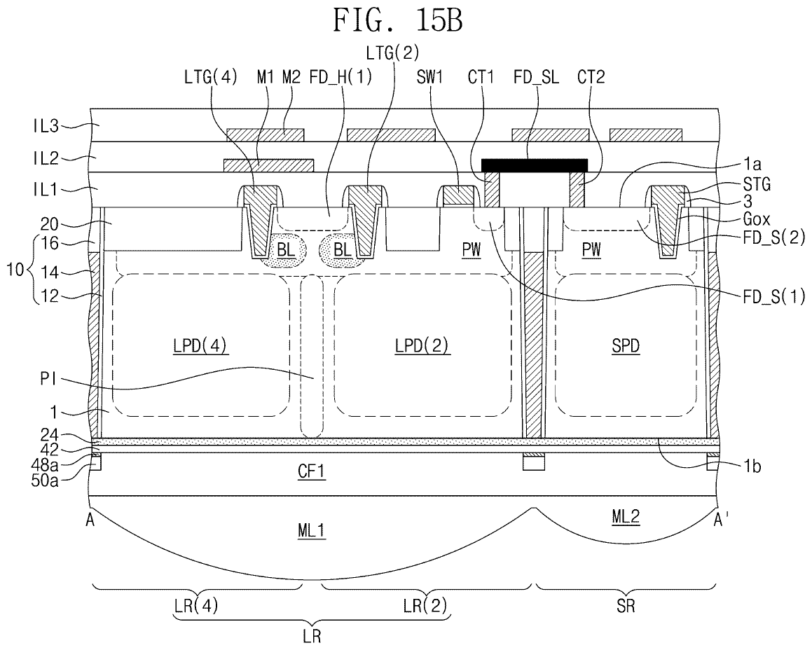

FIG. 15A is a layout illustrating an image sensor according to some example embodiments. FIG. 15B is a sectional view taken along a line A-A′ of FIG. 15A. The layout of FIG. 15A may correspond to one pixel PX of the pixel array of FIG. 2.

Referring to FIGS. 15A and 15B, in the image sensor in some example embodiments, concentrations of the second dopant in the first to fourth sub-large photoelectric conversion parts LPD(1) to LPD(4) may be equal to each other and may be equal to a concentration of the second dopant in the small photoelectric conversion part SPD. The buried regions BL may be overlapped with the first to fourth sub-large transfer gate electrodes LTG(1) to LTG(4), respectively. The buried regions BL may be placed between the first to fourth sub-large photoelectric conversion parts LPD(1) to LPD(4) and the large floating diffusion region FD_H(1). The buried regions BL may lower a shut off potential of the first to fourth sub-large transfer gate electrodes LTG(1) to LTG(4). Thus, it may be possible to suppress a blooming phenomenon. The large light-receiving region LR may be divided into a plurality of regions by the deep isolation pattern 10, and this may make it possible to increase the FWC. Except for the afore-described differences, the image sensor may have substantially the same features as that described with reference to FIGS. 11A and 11B.

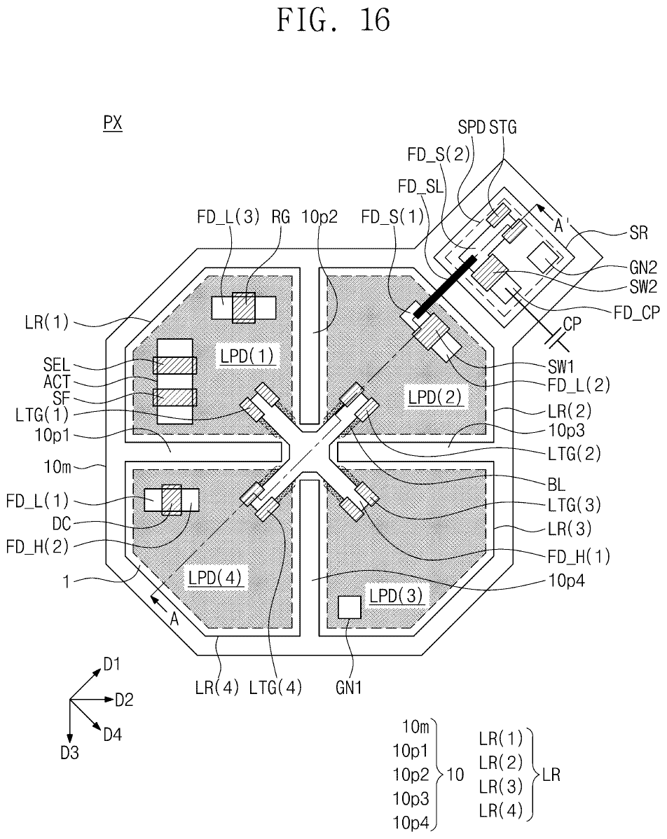

FIG. 16 is a layout illustrating an image sensor according to some example embodiments. The present example embodiments may correspond to one of the combinations of the example embodiments of FIGS. 14, 15A, and 15B. A section taken along a line A-A′ of FIG. 16 may be the same as or similar to FIG. 15B.

Referring to FIGS. 15B and 16, in the image sensor in some example embodiments, concentrations of the second dopant in the first to fourth sub-large photoelectric conversion parts LPD(1) to LPD(4) may be equal to each other and may be higher than a concentration of the second dopant in the small photoelectric conversion part SPD. The buried regions BL may be overlapped with the first to fourth sub-large transfer gate electrodes LTG(1) to LTG(4), respectively. The buried regions BL may be placed between the first to fourth sub-large photoelectric conversion parts LPD(1) to LPD(4) and the large floating diffusion region FD_H(1). The buried regions BL may lower a shut off potential of the first to fourth sub-large transfer gate electrodes LTG(1) to LTG(4). Thus, it may be possible to suppress the blooming phenomenon. The large light-receiving region LR may be divided into a plurality of regions by the deep isolation pattern 10, and this may make it possible to increase the FWC. Except for the afore-described differences, the image sensor may have substantially the same features as that described with reference to FIGS. 14A and 14B.

FIG. 17 is a layout illustrating an image sensor according to some example embodiments.

Referring to FIG. 17, in the image sensor in some example embodiments, the concentrations of the second dopant in the second and third sub-large photoelectric conversion parts LPD(2) and LPD(3) may be equal to each other and may be higher than a concentration of the second dopant in the first and fourth sub-large photoelectric conversion parts LPD(1) and LPD(4). The concentration of the second dopant in the second and third sub-large photoelectric conversion parts LPD(2) and LPD(3) may be higher than, e.g., higher by an order of magnitude than, the concentration of the second dopant in the small photoelectric conversion part SPD. The buried regions BL may be placed between the second and third sub-large photoelectric conversion parts LPD(2) and LPD(3) and the large floating diffusion region FD_H(1). The buried regions BL may lower a shut off potential of the first to fourth sub-large transfer gate electrodes LTG(1) to LTG(4). Thus, it may be possible to suppress the blooming phenomenon. The large light-receiving region LR may be divided into a plurality of regions by the deep isolation pattern 10, and this may make it possible to increase the FWC. Except for the afore-described differences, the image sensor may have substantially the same features as that described with reference to FIGS. 14A and 14B.

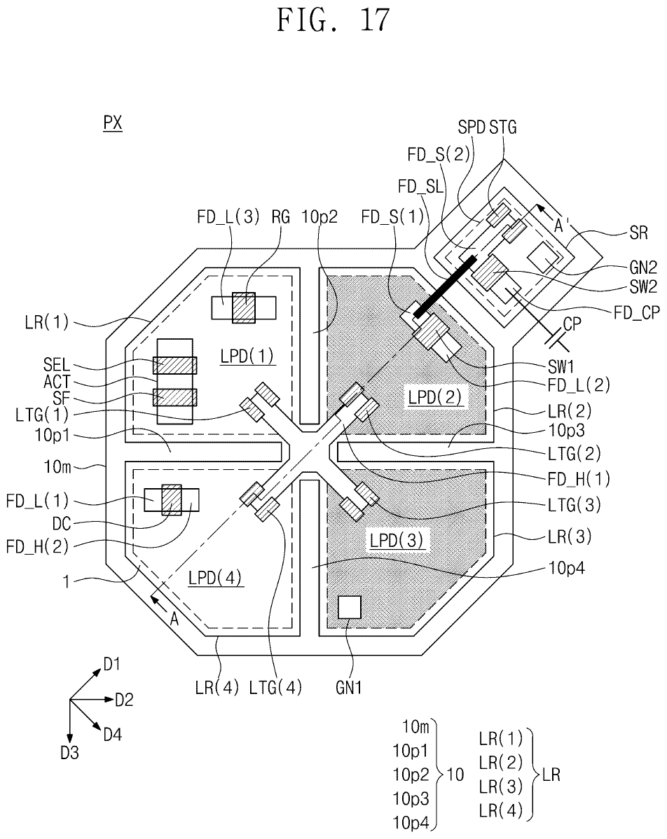

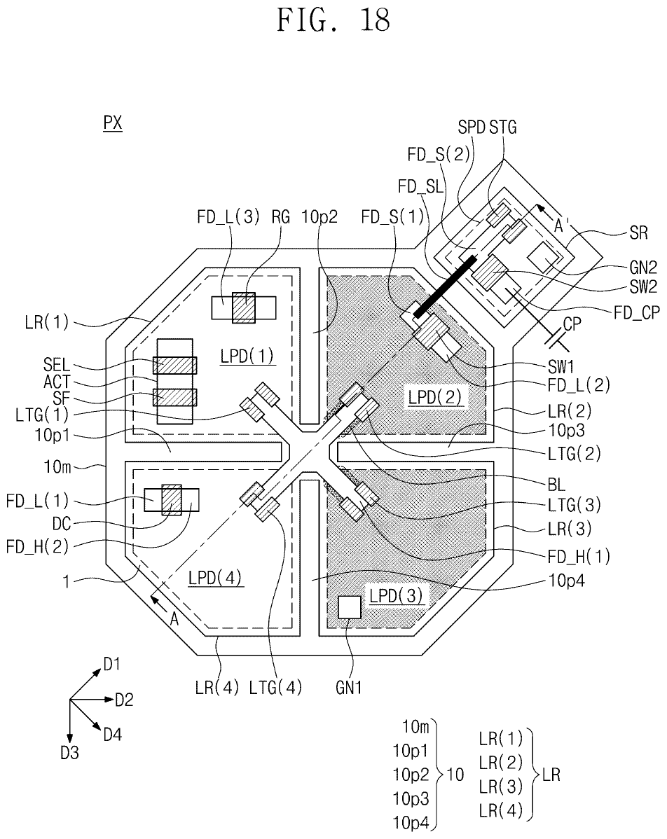

FIG. 18 is a layout illustrating an image sensor according to some example embodiments.

Referring to FIG. 18, the image sensor in some example embodiments may have a structure, in which two buried regions BL are further provided, compared with the structure of FIG. 17. In detail, the concentrations of the second dopant in the second and third sub-large photoelectric conversion parts LPD(2) and LPD(3) may be equal to each other and may be higher than the concentration of the second dopant in the first and fourth sub-large photoelectric conversion parts LPD(1) and LPD(4). The concentrations of the second dopant of the second and third sub-large photoelectric conversion parts LPD(2) and LPD(3) may be higher than the concentration of the second dopant in the small photoelectric conversion part SPD. The buried regions BL may be placed between the second and third sub-large photoelectric conversion parts LPD(2) and LPD(3) and the large floating diffusion region FD_H(1). The buried regions BL may lower a shut off potential of the second and third sub-large transfer gate electrodes LTG(2) and LTG(3). Thus, it may be possible to suppress or at least partly suppress the blooming phenomenon.

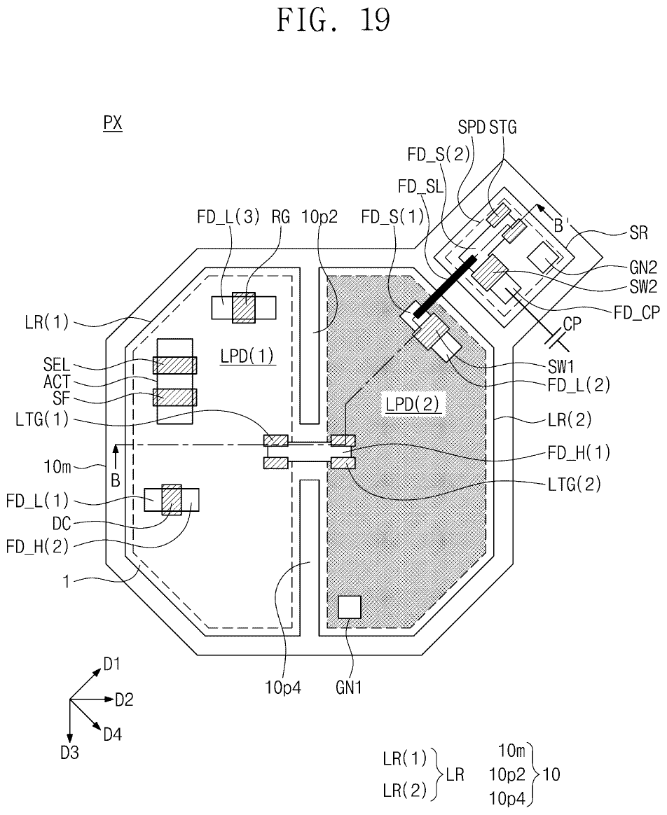

FIG. 19 is a layout illustrating an image sensor according to some example embodiments. A section taken along a line B-B′ of FIG. 19 may be the same as or similar to FIG. 8B.

Referring to FIGS. 8B and 19, in the image sensor in some example embodiments, the deep isolation pattern 10 may divide the large light-receiving region LR into two sub-large light-receiving regions LR(1) and LR(2). The deep isolation pattern 10 may include second and fourth insertion isolation portions 10p2 and 10p4, which are inserted into the large light-receiving region LR, when viewed in a plan view. The second and fourth insertion isolation portions 10p2 and 10p4 may be elongated in the third direction D3. The second and fourth insertion isolation portions 10p2 and 10p4 may be spaced apart from each other, at the center of the large light-receiving region LR. The first and second sub-large light-receiving regions LR(1) and LR(2) may be elongated in the third direction D3 and may be spaced apart from each other in the second direction D2. The second sub-large light-receiving region LR(2) may be closer to the small light-receiving region SR than the first sub-large light-receiving region LR(1).

The first and second sub-large transfer gate electrodes LTG(1) and LTG(2) may be disposed to be adjacent to the center of the large light-receiving region LR. The large floating diffusion regions FD_H(1), which are placed at a side of each of the first and second sub-large transfer gate electrodes LTG(1) and LTG(2), may be connected to each other, at the center of the large light-receiving region LR, and may be provided to have a bar shape that is elongated in the second direction D2, when viewed in a plan view.

The reset gate electrode RG, the reset dopant region FD_L(3), the selection gate electrode SEL, the source follower gate electrode SF, the dual conversion gain gate electrode DC, the first DC dopant region FD_L(1), the second DC dopant region FD_H(2) may be disposed in the first sub-large light-receiving region LR(1).

The first switch gate electrode SW1, the first SW1 dopant region FD_S(1), the second SW1 dopant region FD_L(2), and the first ground region GN1 may be disposed in the second sub-large light-receiving region LR(2).

The first and second sub-large photoelectric conversion parts LPD(1) and LPD(2) may be disposed in the substrate 1 to correspond to the first and second sub-large light-receiving regions LR(1) and LR(2), respectively. The concentration of the second dopant in the second sub-large photoelectric conversion part LPD(2) may be higher than, e.g., by an order of magnitude or more than, the concentration of the second dopant in the first sub-large photoelectric conversion part LPD(1). The concentration of the second dopant in the second sub-large photoelectric conversion part LPD(2) may be higher than the concentration of the second dopant in the small photoelectric conversion part SPD. The unit pixel PX of FIG. 19 may have a circuit structure, from which the thirteenth and fourteenth sub-large transfer transistors TX13 and TX14 in the circuit diagram of FIG. 9 are omitted. Except for the afore-described differences, the image sensor may have the same or substantially the same features as that described above.

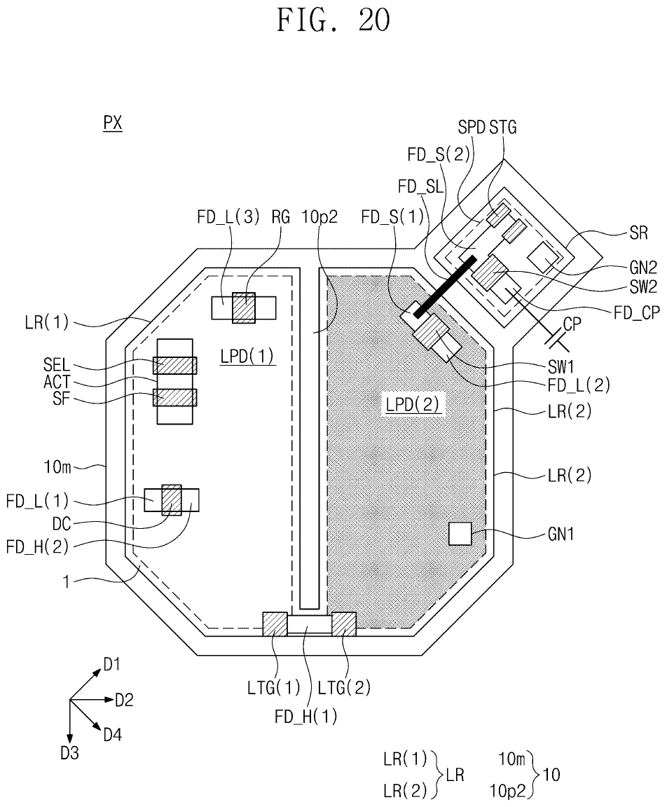

FIG. 20 is a layout illustrating an image sensor according to some example embodiments.

Referring to FIG. 20, in the image sensor in some example embodiments, the deep isolation pattern 10 may have only one insertion isolation portion 10p2, which is inserted into the large light-receiving region LR, when viewed in a plan view. A second insertion isolation portion 10p2 may divide the large light-receiving region LR into two sub-large light-receiving regions LR(1) and LR(2). The second insertion isolation portion 10p2 may be extended from a side surface of the main isolation portion 10m in the third direction D3 to cross the center of the large light-receiving region LR but may be spaced apart from an opposite side surface of the main isolation portion 10m. The large floating diffusion region FD_H(1) and the first and second large transfer gate electrodes LTG(1) and LTG(2) may be adjacent to the opposite side surface of the main isolation portion 10m.

The first and second sub-large photoelectric conversion parts LPD(1) and LPD(2) may be disposed in the substrate 1 to correspond to the first and second sub-large light-receiving regions LR(1) and LR(2), respectively. The concentration of the second dopant in the second sub-large photoelectric conversion part LPD(2) may be higher than the concentration of the second dopant in the first sub-large photoelectric conversion part LPD(1). The concentration of the second dopant in the second sub-large photoelectric conversion part LPD(2) may be higher than the concentration of the second dopant in the small photoelectric conversion part SPD. Except for the afore-described differences, the image sensor may have substantially the same features as that described with reference to FIG. 19.

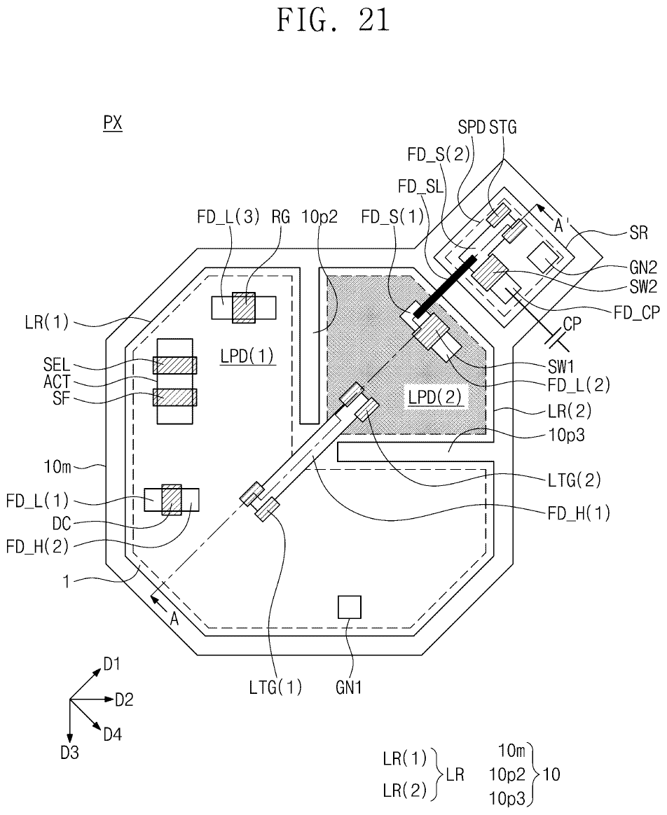

FIG. 21 is a layout illustrating an image sensor according to some example embodiments.

Referring to FIG. 21, in the image sensor in some example embodiments, a deep isolation pattern may include the second and third insertion isolation portions 10p2 and 10p3, which are inserted into the large light-receiving region LR, when viewed in a plan view. The second and third insertion isolation portions 10p2 and 10p3 may divide the large light-receiving region LR into two sub-large light-receiving regions LR(1) and LR(2). The second and third insertion isolation portions 10p2 and 10p3 may be spaced apart from each other at the center of the large light-receiving region LR.

When viewed in a plan view, the first sub-large light-receiving region LR(1) may have an ‘L’ shaped structure, in which the first, third, and fourth sub-large light-receiving regions LR(1), LR(3), and LR(4) of FIG. 8A are merged. The second sub-large light-receiving region LR(2) may be placed between the first sub-large light-receiving region LR(1) and the small light-receiving region SR. The first ground region GN1 may be placed in the first sub-large light-receiving region LR(1). The large floating diffusion regions FD_H(1) may be connected to each other at the center of the large light-receiving region LR and may have a bar shape that is elongated in the first direction D1, when viewed in a plan view.

The first and second sub-large photoelectric conversion parts LPD(1) and LPD(2) may be disposed in the substrate 1 to correspond to the first and second sub-large light-receiving regions LR(1) and LR(2), respectively. The concentration of the second dopant in the second sub-large photoelectric conversion part LPD(2) may be higher than the concentration of the second dopant in the first sub-large photoelectric conversion part LPD(1). The concentration of the second dopant in the second sub-large photoelectric conversion part LPD(2) may be higher than the concentration of the second dopant in the small photoelectric conversion part SPD. Except for the afore-described differences, the image sensor may have substantially the same features as that described with reference to FIG. 19.

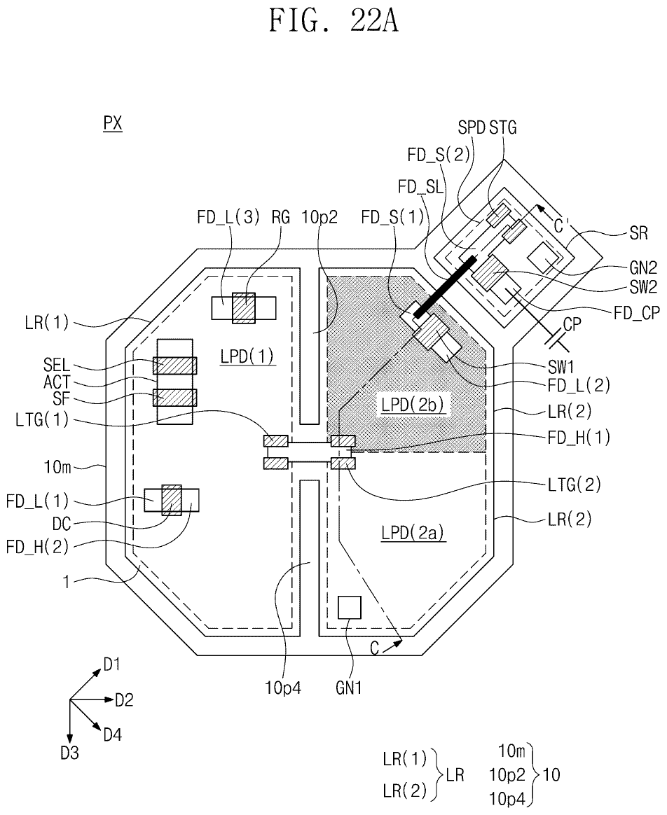

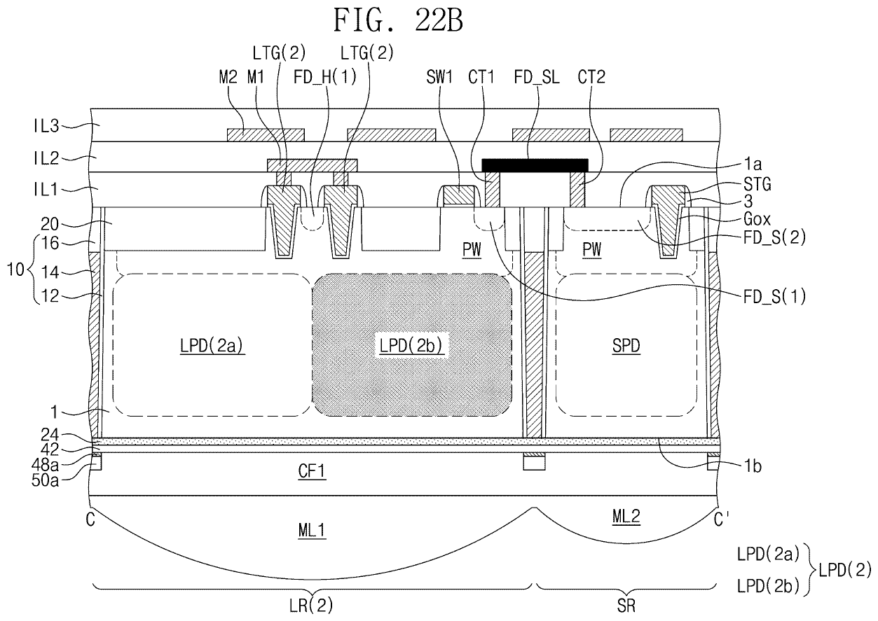

FIG. 22A is a layout illustrating an image sensor according to some example embodiments. FIG. 22B is a sectional view taken along a line C-C′ of FIG. 22A.

Referring to FIGS. 22A and 22B, in the image sensor of FIG. 22A, the structure of the deep isolation pattern 10, the position of the large floating diffusion region FD_H(1), and arrangement of the gate electrodes may be the same as those in FIG. 19. However, the second sub-large photoelectric conversion part LPD(2), which is disposed in the second sub-large light-receiving region LR(2), may be divided into a low concentration photoelectric conversion part LPD(2a) and a high concentration photoelectric conversion part LPD(2b). The deep isolation pattern 10 or the isolation region PI of FIG. 8B may not be interposed between the low concentration photoelectric conversion part LPD(2a) and the high concentration photoelectric conversion part LPD(2b). The low concentration photoelectric conversion part LPD(2a) may be in contact with the high concentration photoelectric conversion part LPD(2b). Each of the low concentration photoelectric conversion part LPD(2a) and the high concentration photoelectric conversion part LPD(2b) may be doped with second dopants of the second conductivity type. The concentration of the second dopant in the high concentration photoelectric conversion part LPD(2b) may be higher than the concentration of the second dopant in the low concentration photoelectric conversion part LPD(2a). The concentration of the second dopant in the photoelectric conversion part LPD(2b) may be higher than the concentration of the second dopant in the first sub-large photoelectric conversion part LPD(1) and the small photoelectric conversion part SPD.

The high concentration photoelectric conversion part LPD(2b) may be closer to the small light-receiving region SR than the low concentration photoelectric conversion part LPD(2a). The first switch gate electrode SW1, the first SW1 dopant region FD_S(1), and the second SW1 dopant region FD_L(2) may be disposed on the high concentration photoelectric conversion part LPD(2b). One of the second sub-large transfer gate electrodes LTG(2) may be placed on the high concentration photoelectric conversion part LPD(2b), and another may be placed on the low concentration photoelectric conversion part LPD(2a). The second sub-large transfer gate electrodes LTG(2) may be connected to one of the first interconnection lines M1. Except for the afore-described differences, the image sensor may have substantially the same features as that described with reference to FIG. 19.

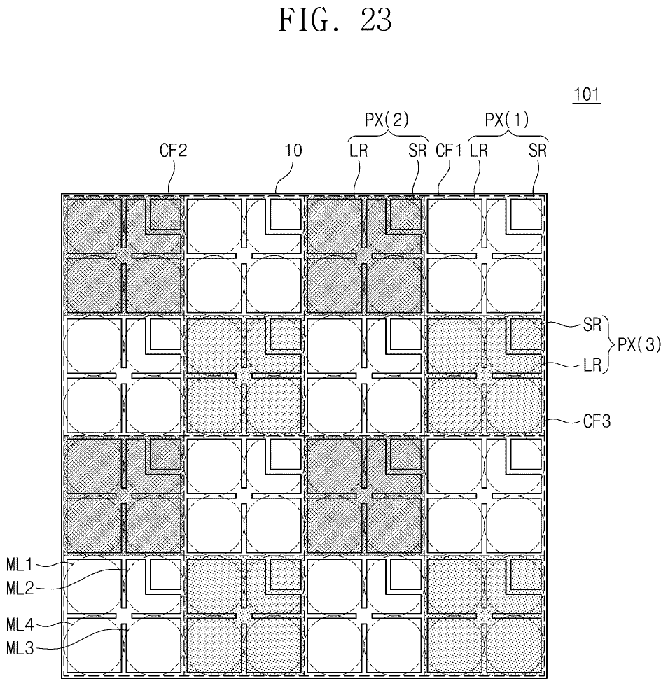

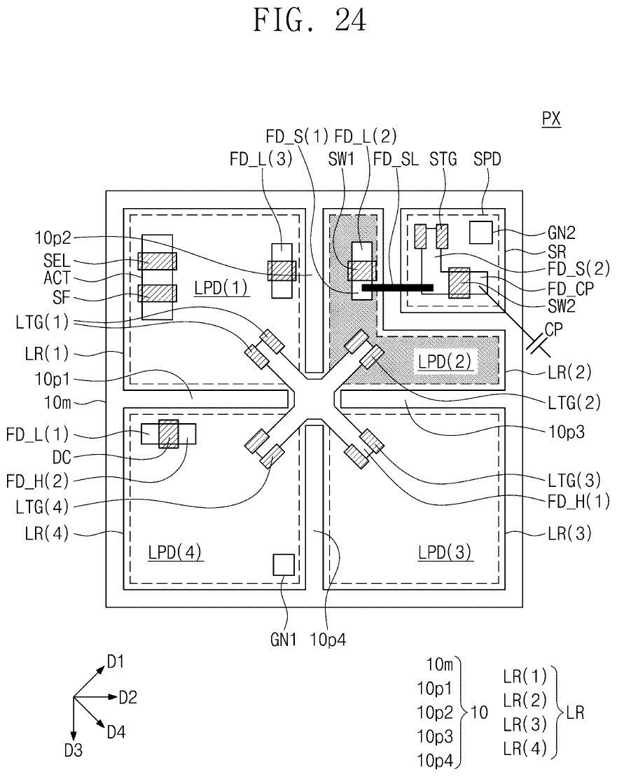

FIG. 23 is a layout illustrating an image sensor according to some example embodiments. FIG. 24 is a layout illustrating an image sensor according to some example embodiments. The layout of FIG. 24 may correspond to one pixel PX of the pixel array of FIG. 23.

Referring to FIGS. 23 and 24, in an image sensor 101 in some example embodiments, the deep isolation pattern 10 may be disposed in the substrate 1 (e.g., see FIG. 3B) to delimit the first to third pixels PX(1) to PX(3), which are separated from each other. The first to third pixels PX(1) to PX(3) may be two-dimensionally arranged in the second and third directions D2 and D3 which are orthogonal to each other. Each of the first to third pixels PX(1) to PX(3) may have a square shape. Each of the first to third pixels PX(1) to PX(3) may include the large light-receiving region LR and the small light-receiving region SR. The small light-receiving region SR may be placed at a corner of each of the pixels PX(1) to PX(3). A portion of the deep isolation pattern 10 may be inserted into the large light-receiving region LR to divide the large light-receiving region LR into four sub-large light-receiving regions LR(1) to LR(4). Each of the pixels PX(1) to PX(3) may be covered with the first to fourth micro lenses ML1 to ML4, which are arranged in a clockwise direction to form a 2×2 matrix shape. That is, each pixel PX may be covered with the first to fourth micro lenses ML1 to ML4, which are arranged in a 2×2 matrix shape. In each pixel PX, the sub-large light-receiving regions LR(1) to LR(4) may be overlapped with the micro lenses ML1 to ML4, respectively, to correspond to the micro lenses ML1 to ML4. The second micro lens ML2 may cover both the second sub-large light-receiving region LR(2) and the small light-receiving region SR. Except for the afore-described differences, the image sensor may have substantially the same features as that described with reference to FIG. 2.

Referring to FIG. 24, in the image sensor in some example embodiments, each pixel PX may have a square shape. Each pixel PX may include the large light-receiving region LR and the small light-receiving region SR. The small light-receiving region SR may be placed at a corner of the pixel PX. A portion of the deep isolation pattern 10 may be inserted into the large light-receiving region LR to divide the large light-receiving region LR into four sub-large light-receiving regions LR(1) to LR(4). In detail, the deep isolation pattern 10 may include the main isolation portion 10m and the first to fourth insertion isolation portions 10p1 to 10p4. The first to fourth sub-large light-receiving regions LR(1) to LR(4) may be disposed in a clockwise direction. The second sub-large light-receiving region LR(1) may be adjacent to the small light-receiving region SR. When viewed in a plan view, the first, third, and fourth sub-large light-receiving regions LR(1), LR(3), and LR(4) may have a square-like shape, and the second sub-large light-receiving region LR(1) may have an L shape. Except for the afore-described differences, the image sensor may have substantially the same features as that described with reference to FIGS. 8A to 10.

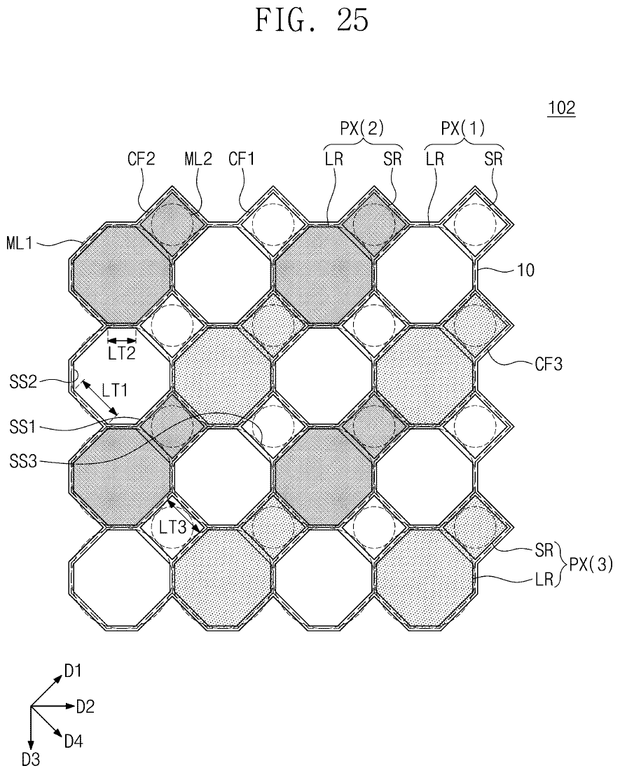

FIG. 25 is a layout illustrating an image sensor according to some example embodiments.

Referring to FIG. 25, in an image sensor 102 in some example embodiments, the deep isolation pattern 10 may be disposed in the substrate 1 (e.g., see FIG. 3B) to define the first to third pixels PX(1) to PX(3), which are separated from each other. Each of the first to third pixels PX(1) to PX(3) may include the large light-receiving region LR and the small light-receiving region SR. In each of the pixels PX(1) to PX(3), the large and small light-receiving regions LR and SR may be arranged side by side in the first direction D1. In each of the first to third pixels PX(1) to PX(3), the large and small light-receiving regions LR and SR may be arranged side by side in the first direction D1. The large light-receiving region LR may have an octagonal shape, which is formed by alternatively and repeatedly disposing the first side surfaces SS1 and the second side surfaces SS2, when viewed in a plan view. The small light-receiving region SR may be adjacent to one of the first side surfaces SS1. The small light-receiving region SR may have a square shape, which is composed of the third side surfaces SS3, when viewed in a plan view. The first side surface SS1 may have the first length LT1. The second side surface SS2 may have the second length LT2 smaller than the first length LT1. The third length LT3 may be equal to or smaller than the first length LT1. Except for the afore-described differences, the image sensor may have substantially the same features as that described with reference to FIG. 2.

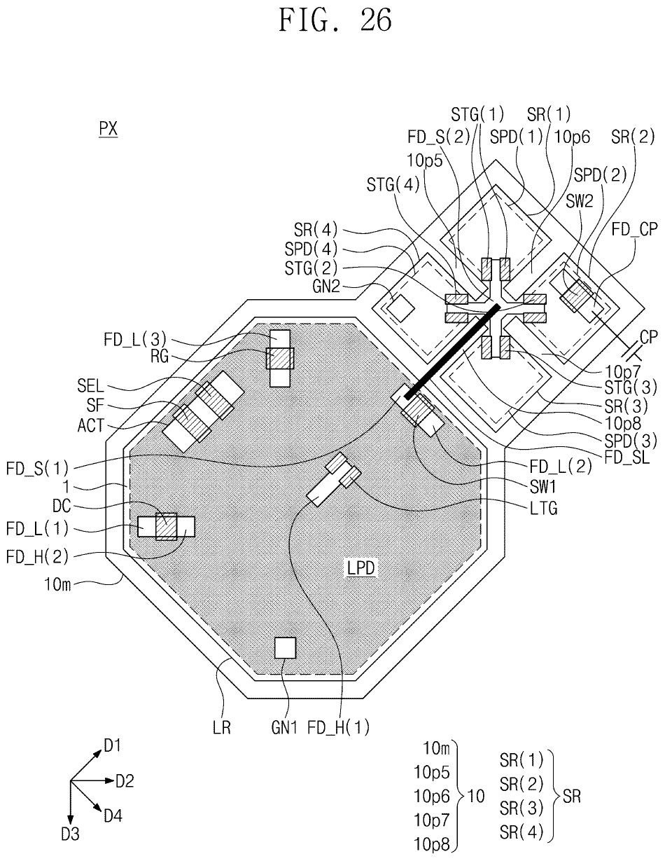

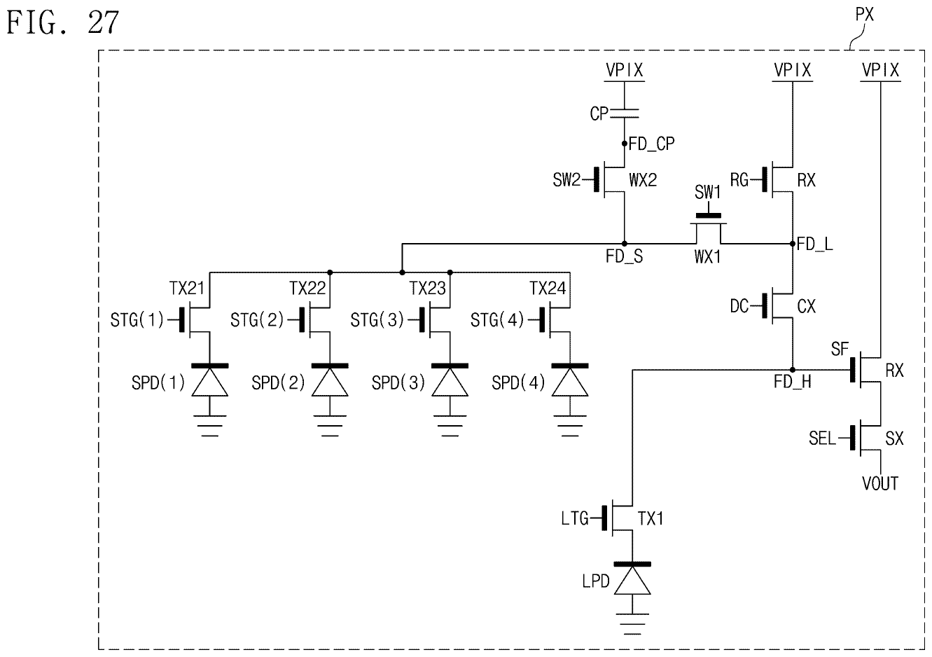

FIG. 26 is a layout illustrating an image sensor according to some example embodiments. The layout of FIG. 26 may correspond to one pixel PX of the pixel array of FIG. 25. FIG. 27 is a circuit diagram illustrating the image sensor of FIG. 26.

Referring to FIG. 26, in the image sensor in some example embodiments, the large light-receiving region LR may not be divided by the deep isolation pattern 10, but the small light-receiving region SR may be divided into four sub-small light-receiving regions SR(1) to SR(4) by the deep isolation pattern 10. The deep isolation pattern 10 may include the main isolation portion 10m and fifth to eighth insertion isolation portions 10p5 to 10p8. The first to fourth sub-small light-receiving regions SR(1) to SR(4) may be disposed in a clockwise direction. The first to fourth sub-small photoelectric conversion parts SPD(1) to SPD(4) may be disposed in the substrate 1 to correspond to the first to fourth sub-small light-receiving regions SR(1) to SR(4), respectively. The first to fourth sub-small photoelectric conversion parts SPD(1) to SPD(4) may be doped with second dopants to have the same or substantially the same concentration. Concentrations of the second dopant in the first to fourth sub-small photoelectric conversion parts SPD(1) to SPD(4) may be lower than a concentration of the second dopant in the large photoelectric conversion part LPD.

First to fourth sub-small transfer gate electrodes STG(1) to STG(4) may be respectively disposed to correspond to the first to fourth sub-small light-receiving regions SR(1) to SR(4). Each of the sub-small transfer gate electrodes STG(1) to STG(4) may be provided in plural. The small floating diffusion region FD_S(2) may be disposed at a side of each of the sub-small transfer gate electrodes STG(1) to STG(4). The small floating diffusion regions FD_S(2) may be connected to each other at a center of the small light-receiving region SR to form an ‘X’ shape, when viewed in a plan view. The second switch gate electrode SW2 may be disposed in the second sub-small light-receiving region SR(2). The second ground region GN2 may be disposed in the fourth sub-small light-receiving region SR(4).

Referring to FIGS. 26 and 27, in the unit pixel PX of the image sensor in some example embodiments, the first sub-small transfer gate electrode STG(1) and the small floating diffusion region FD_S(2), which are adjacent to each other, may constitute a 21-th sub-small transfer transistor TX21. The second sub-small transfer gate electrode STG(2) and the small floating diffusion region FD_S(2), which are adjacent to each other, may constitute a 22-th sub-small transfer transistor TX22. The third sub-small transfer gate electrode STG(3) and the small floating diffusion region FD_S(2), which are adjacent to each other, may constitute a 23-th sub-small transfer transistor TX23. The fourth sub-small transfer gate electrode STG(4) and the small floating diffusion region FD_S(2), which are adjacent to each other, may constitute a 24-th sub-small transfer transistor TX24. The unit pixel PX of the image sensor in some example embodiments may have a structure, in which four sub-small transfer transistors TX21 to TX24 are connected to the third charge detection node FD_S in the circuit diagram of FIG. 4A. The sub-small transfer transistors TX21 to TX24 may be simultaneously or sequentially turned on. Except for the afore-described differences, the image sensor may have substantially the same or similar features as that described with reference to FIG. 3A.

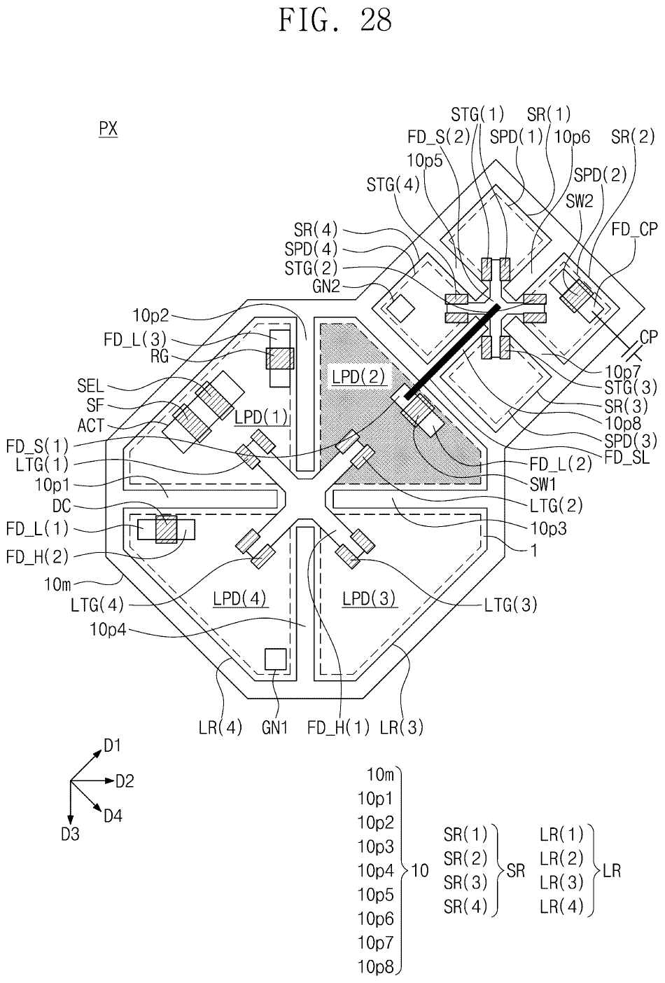

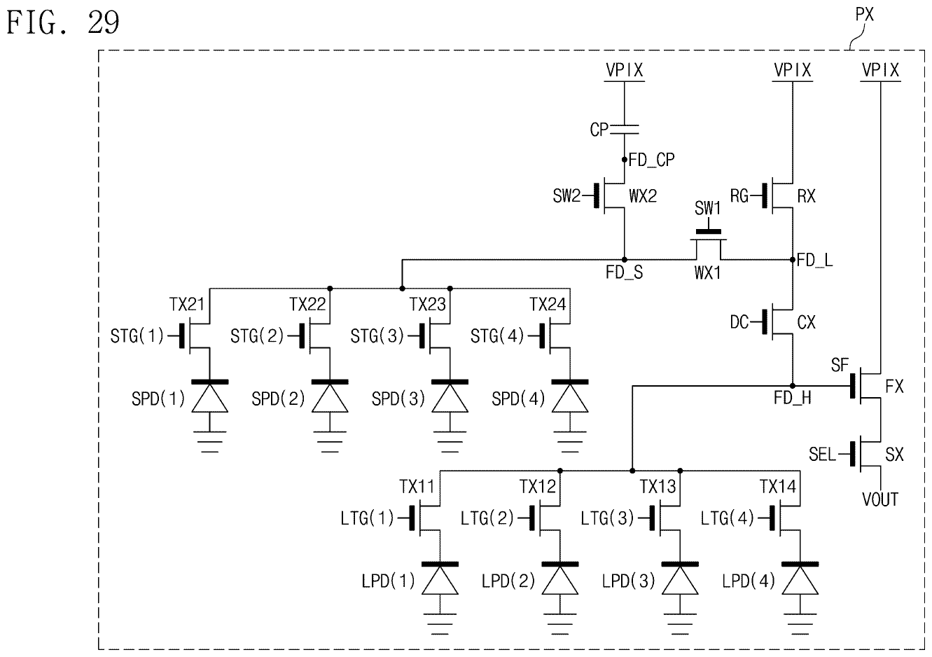

FIG. 28 is a layout illustrating an image sensor according to some example embodiments. The layout of FIG. 28 may correspond to one pixel PX of the pixel array of FIG. 25. FIG. 29 is a circuit diagram illustrating the image sensor of FIG. 28.

Referring to FIGS. 28 and 29, in the image sensor in some example embodiments, the deep isolation pattern 10 may be inserted into the large light-receiving region LR to form four sub-large light-receiving regions LR(1) to LR(4), which are separated from each other, and the deep isolation pattern 10 may be inserted into the small light-receiving region SR to form four sub-small light-receiving regions SR(1) to SR(4), which are separated from each other. In some example embodiments, the image sensor may have a structure, in which the large light-receiving region LR of FIG. 8A and the small light-receiving region SR of FIG. 26 are combined. The deep isolation pattern 10 may include the main isolation portion 10m and the first to eighth insertion isolation portions 10p1 to 10p8. The first to fourth insertion isolation portions 10p1 to 10p4 may be spaced apart from each other at the center of the large light-receiving region LR. The fifth to eighth insertion isolation portions 10p5 to 10p8 may be spaced apart from each other at the center of the small light-receiving region SR.

A concentration of the second dopant in the second sub-large photoelectric conversion part LPD(2) may be higher than concentrations of the second dopant in the first, third, and fourth sub-large photoelectric conversion parts LPD(1), LPD(3), and LPD(4) and the first to fourth sub-small photoelectric conversion parts SPD(1) to SPD(4). The unit pixel PX of the image sensor in some example embodiments may have a structure, in which four sub-large transfer transistors TX11 to TX14 are connected to the first charge detection node FD_H and four sub-small transfer transistors TX21 to TX24 are connected to the third charge detection node FD_S, compared with the circuit diagram of FIG. 4A. Except for the afore-described differences, the image sensor may have substantially the same features as that described with reference to FIGS. 8A and 26.

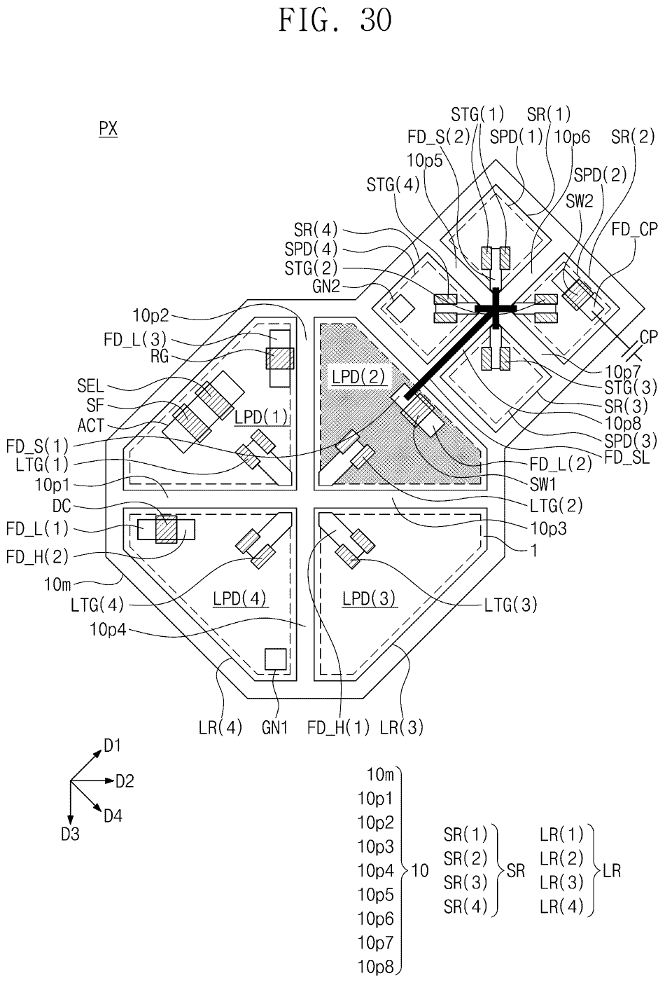

FIG. 30 is a layout illustrating an image sensor according to some example embodiments. The layout of FIG. 30 may correspond to one pixel PX of the pixel array of FIG. 25.

Referring to FIG. 30, in the image sensor in some example embodiments, the first to fourth insertion isolation portions 10p1 to 10p4 may be connected to each other at the center of the large light-receiving region LR. Thus, the large floating diffusion regions FD_H(1) in the first to fourth sub-large light-receiving regions LR(1) to LR(4) may be spaced apart from each other. The fifth to eighth insertion isolation portions 10p5 to 10p8 may be connected to each other at the center of the small light-receiving region SR. Thus, the small floating diffusion regions FD_S(2) in the first to fourth sub-small light-receiving regions SR(1) to SR(4) may be spaced apart from each other. Except for the afore-described differences, the image sensor may have substantially the same features as that described with reference to FIG. 28.

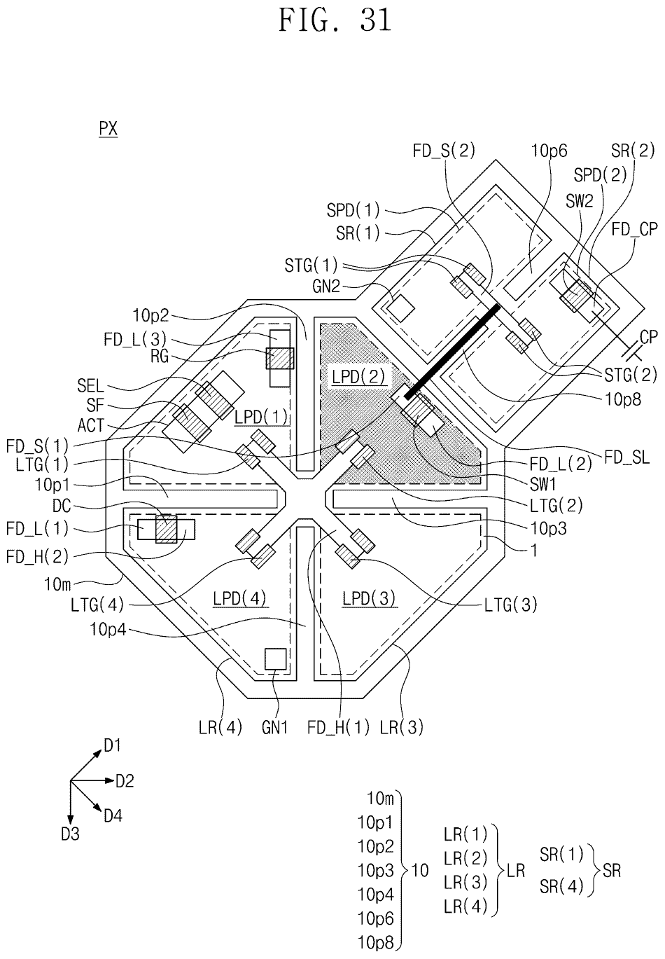

FIG. 31 is a layout illustrating an image sensor according to some example embodiments. The layout of FIG. 31 may correspond to one pixel PX of the pixel array of FIG. 25.

Referring to FIG. 31, in the image sensor in some example embodiments, the sixth and eighth insertion isolation portions 10p6 and 10p8 of the deep isolation pattern 10 in the structure of FIG. 28 may be inserted into the small light-receiving region SR to divide the small light-receiving region SR into two sub-small light-receiving regions SR(1) and SR(2). The second ground region GN2 may be disposed in the first sub-small light-receiving region SR(1), and the second switch gate electrode SW2 may be disposed in the second sub-small light-receiving region SR(2). The small floating diffusion regions FD_S(2) may be connected to each other to form a bar shape that is elongated in the fourth direction D4.

The concentration of the second dopant in the second sub-large photoelectric conversion part LPD(2) may be higher than the concentration of the second dopant in the first, third, and fourth sub-large photoelectric conversion parts LPD(1), LPD(3), and LPD(4) and the first and second sub-small photoelectric conversion parts SPD(1) and SPD(2). The unit pixel PX of the image sensor in some example embodiments may have a structure, from which the 23-th and 24-th sub-small transfer transistors TX23 and TX24 in the circuit diagram of FIG. 29 are omitted. Except for the afore-described differences, the image sensor may have substantially the same features as that described with reference to FIGS. 8A and 26.

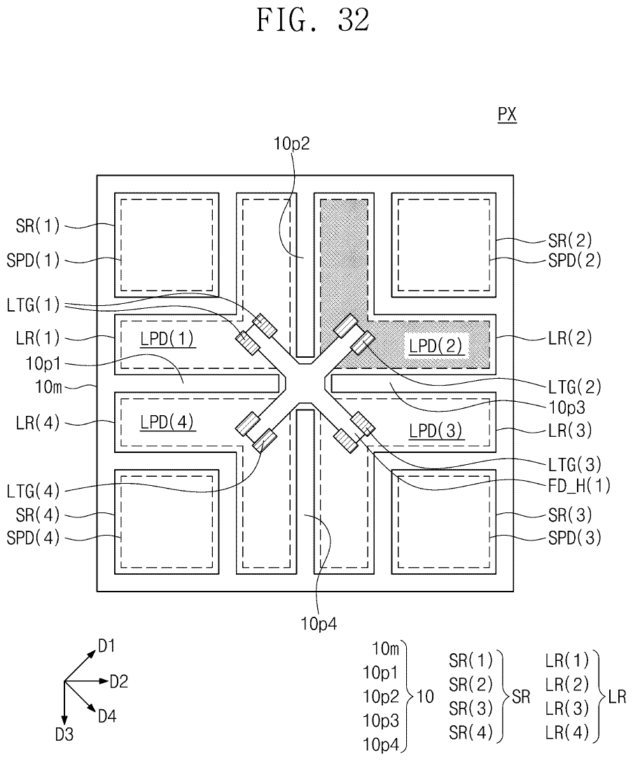

FIG. 32 is a layout illustrating an image sensor according to some example embodiments. The layout of FIG. 32 may correspond to one pixel PX of the pixel array of FIG. 23.

Referring to FIGS. 23 and 32, in the image sensor in some example embodiments, each pixel PX may have a square shape. Each pixel PX may include the large light-receiving region LR and the small light-receiving region SR. The small light-receiving region SR may be placed at a corner of the pixel PX. The small light-receiving region SR may include the first to fourth sub-small light-receiving regions SR(1) to SR(4) which are arranged in a clockwise direction. The first to fourth sub-small light-receiving regions SR(1) to SR(4) may be disposed at respective positions corresponding to four corners of the pixel PX. The large light-receiving region LR may include the first to fourth sub-large light-receiving regions LR(1) to LR(4), which are arranged in a clockwise direction. Each of the first to fourth sub-large light-receiving regions LR(1) to LR(4) may have an ‘L’ shape, when viewed in a plan view.

Referring to FIGS. 23 and 32, the first sub-large light-receiving region LR(1) and the first sub-small light-receiving region SR(1) may be covered with the first micro lens ML1. The second sub-large light-receiving region LR(2) and the second sub-small light-receiving region SR(2) may be covered with the second micro lens ML2. The third sub-large light-receiving region LR(3) and the third sub-small light-receiving region SR(3) may be covered with the third micro lens ML3. The fourth sub-large light-receiving region LR(4) and the fourth sub-small light-receiving region SR(4) may be covered with the fourth micro lens ML4.

A concentration of the second dopant in the second sub-large photoelectric conversion part LPD(2) may be higher than, e.g., by an order of magnitude or more than, concentrations of the second dopant in the first, third, and fourth sub-large photoelectric conversion parts LPD(1), LPD(3), and LPD(4) and the first to fourth sub-small photoelectric conversion parts SPD(1) to SPD(4). Except for the afore-described differences, the image sensor may have substantially the same features as that described with reference to FIGS. 23 and 24.

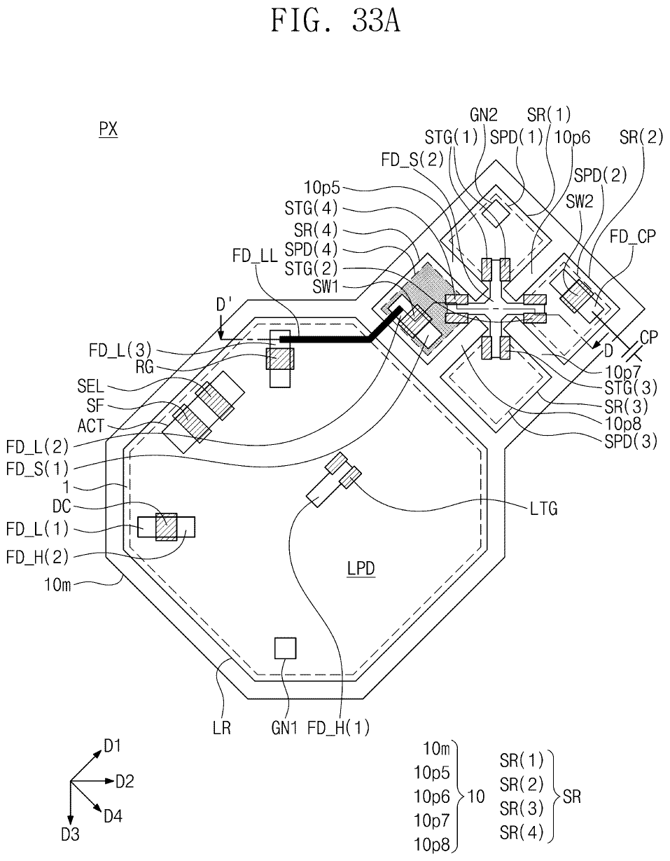

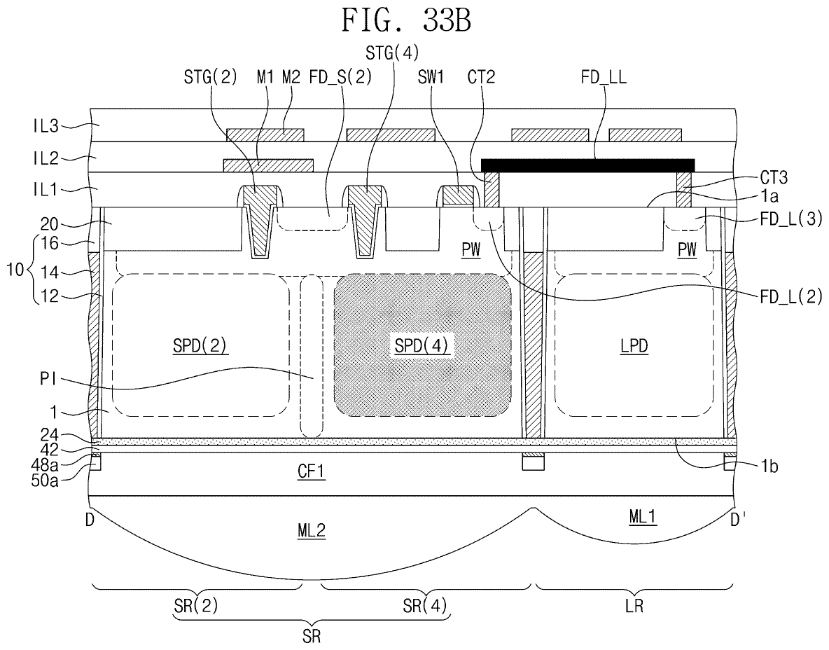

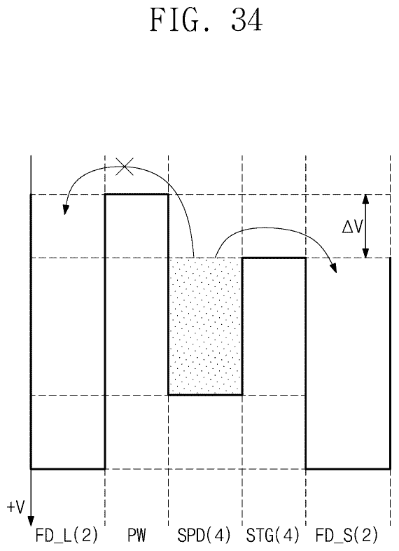

FIG. 33A is a layout illustrating an image sensor according to some example embodiments. FIG. 33B is a sectional view taken along a line D-D′ of FIG. 33A. The layout of FIG. 33A may correspond to one pixel PX of the pixel array of FIG. 25. FIG. 34 is a potential diagram illustrating the image sensor of FIG. 33A.

The deep isolation pattern 10 in FIGS. 33A and 33B may have the same structure as that in FIG. 26. However, a concentration of the second dopant of the fourth sub-small photoelectric conversion part SPD(4) may be higher than concentrations of the second dopant of the first to third sub-small photoelectric conversion parts SPD(1) to SPD(3) and the large photoelectric conversion part LPD. The first switch transistor WX1 including the first switch gate electrode SW1, the first SW1 dopant region FD_S(1), and the second SW1 dopant region FD_L(2) may be disposed in fourth sub-small light-receiving region SR(4). The second SW1 dopant region FD_L(2) may be connected to the second contact plug CT2. The reset dopant region FD_L(3), which is disposed in the large light-receiving region LR, may be connected to a third contact plug CT3. A second node connection line FD_LL may connect the second contact plug CT2 to the third contact plug CT3. In other words, the second node connection line FD_LL may connect the second SW1 dopant region FD_L(2) to the reset dopant region FD_L(3).

Referring to FIGS. 33A, 33B, and 34, if a pixel signal is output in proportion to an amount of photocharges accumulated in the large photoelectric conversion part LPD, electric charges, which are generated in the fourth sub-small photoelectric conversion part SPD(4) by high intensity light incident into the image sensor, may be overflown to the second SW1 dopant region FD_L(2) beyond a potential barrier in the well region PW. The overflown photocharges may be transferred to the reset dopant region FD_L(3) through the second node connection line FD_LL. In this case, there may be a blooming phenomenon distorting the pixel signal output from the small photoelectric conversion part SPD and/or having a signal loss issue.

However, in the image sensor according to some example embodiments, since the concentration of the second dopant in the fourth sub-small photoelectric conversion part SPD(4) is larger than the concentration of the second dopant in the large photoelectric conversion part LPD, an electrostatic potential of the fourth sub-small transfer gate electrode STG(4) may be lowered by a potential difference ΔV, compared with an electric potential in the well region PW, and a shut off potential may be lowered. The fourth sub-small transfer gate electrode STG(4) may be in a low shut off state. Thus, it may be possible to prevent or reduce a blooming phenomenon from the small light-receiving region SR to the large light-receiving region LR and thereby to realize a clearer image.

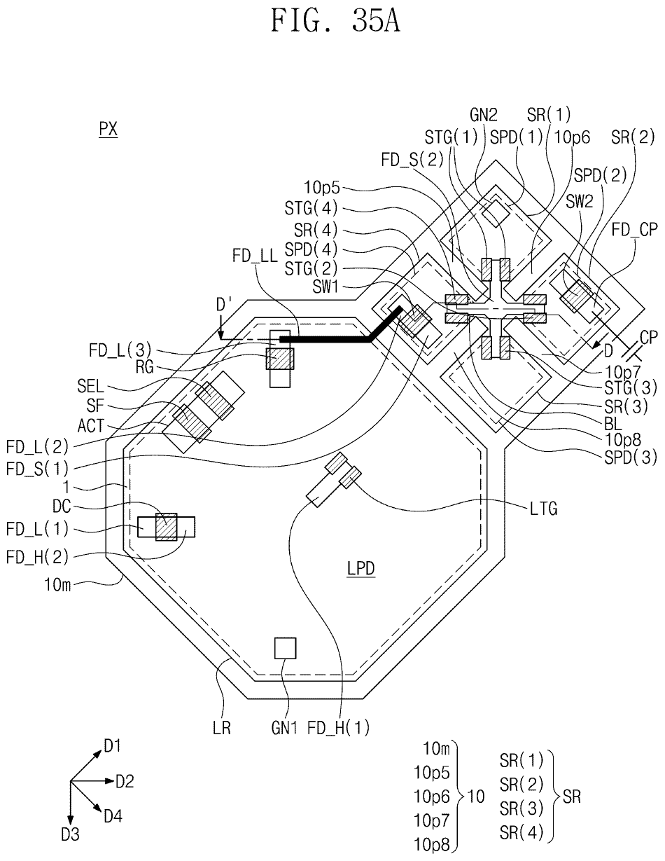

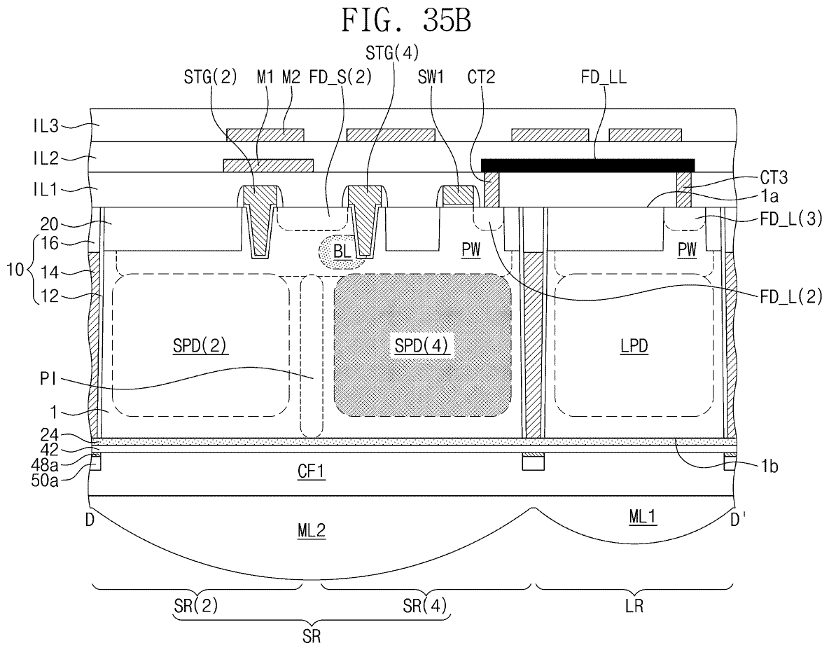

FIG. 35A is a layout illustrating an image sensor according to some example embodiments. FIG. 35B is a sectional view taken along a line D-D′ of FIG. 35A. The layout of FIG. 35A may correspond to one pixel PX of the pixel array of FIG. 25.

Referring to FIGS. 35A and 35B, the concentration of the second dopant may be the same in the first to fourth sub-small photoelectric conversion parts SPD(1) to SPD(4) and the large photoelectric conversion part LPD. However, the buried region BL may be disposed between the fourth sub-small photoelectric conversion part SPD(4) and the small floating diffusion region FD_S(2). The buried region BL may be the same as that in the embodiment described with reference to FIGS. 6A and 6B.

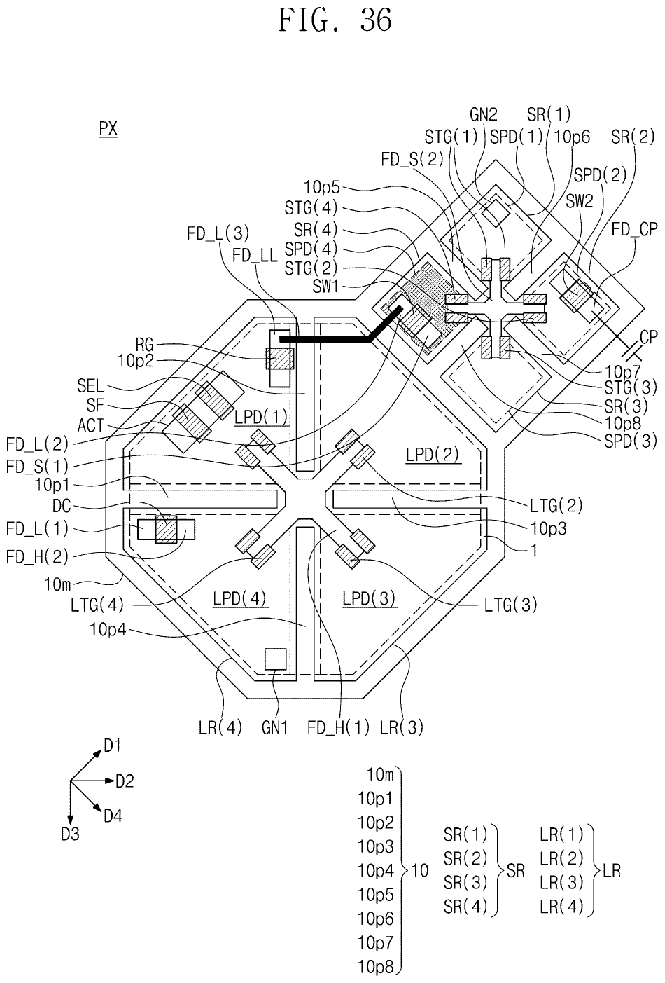

FIG. 36 is a layout illustrating an image sensor according to some example embodiments. The layout of FIG. 36 may correspond to one pixel PX of the pixel array of FIG. 25.

Referring to FIG. 36, in the image sensor in some example embodiments, the large light-receiving region LR in the structure of FIG. 33A may be divided into four sub-large light-receiving regions LR(1) to LR(4) by the first to fourth insertion isolation portions 10p1 to 10p4 of the deep isolation pattern 10. A concentration of the second dopant in the fourth sub-small photoelectric conversion part SPD(4) may be higher than concentrations of the second dopant in the first to third sub-small photoelectric conversion parts SPD(1) to SPD(3) and the first to fourth sub-large photoelectric conversion parts LPD(1) to LPD(4). Except for the afore-described differences, the image sensor may have substantially the same features as that described with reference to FIGS. 30 and 33A.

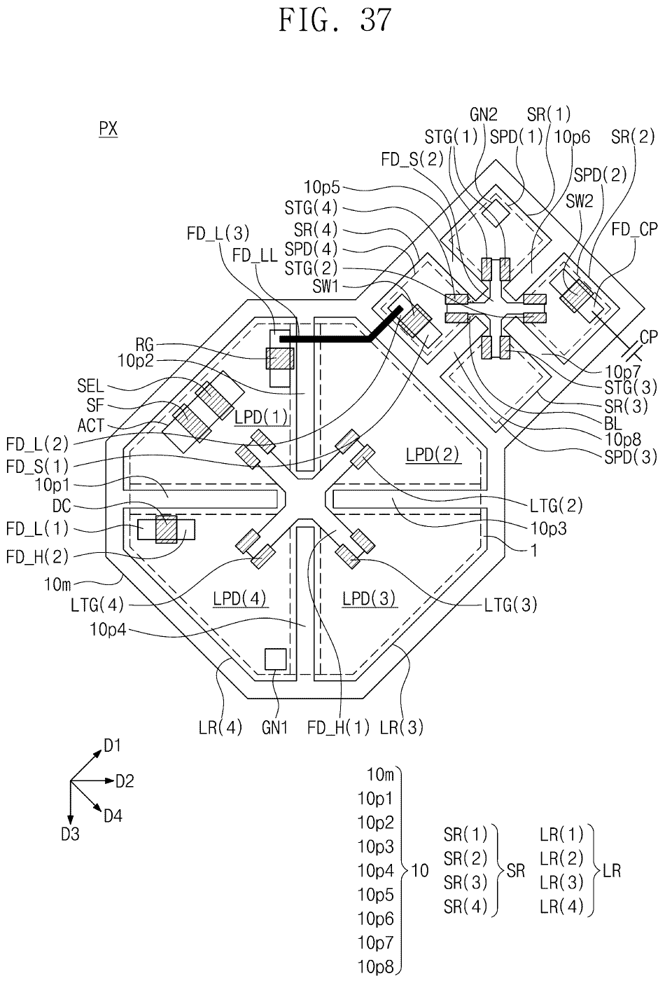

FIG. 37 is a layout illustrating an image sensor according to some example embodiments. The layout of FIG. 37 may correspond to one pixel PX of the pixel array of FIG. 25.

Referring to FIG. 37, concentrations of the second dopant in the first to fourth sub-small photoelectric conversion parts SPD(1) to SPD(4) and the first to fourth sub-large photoelectric conversion parts LPD(1) to LPD(4) may be equal to each other. However, the buried region BL may be disposed between the fourth sub-small photoelectric conversion part SPD(4) and the small floating diffusion region FD_S(2). The buried region BL may be the same as that in the embodiment described with reference to FIGS. 6A and 6B.

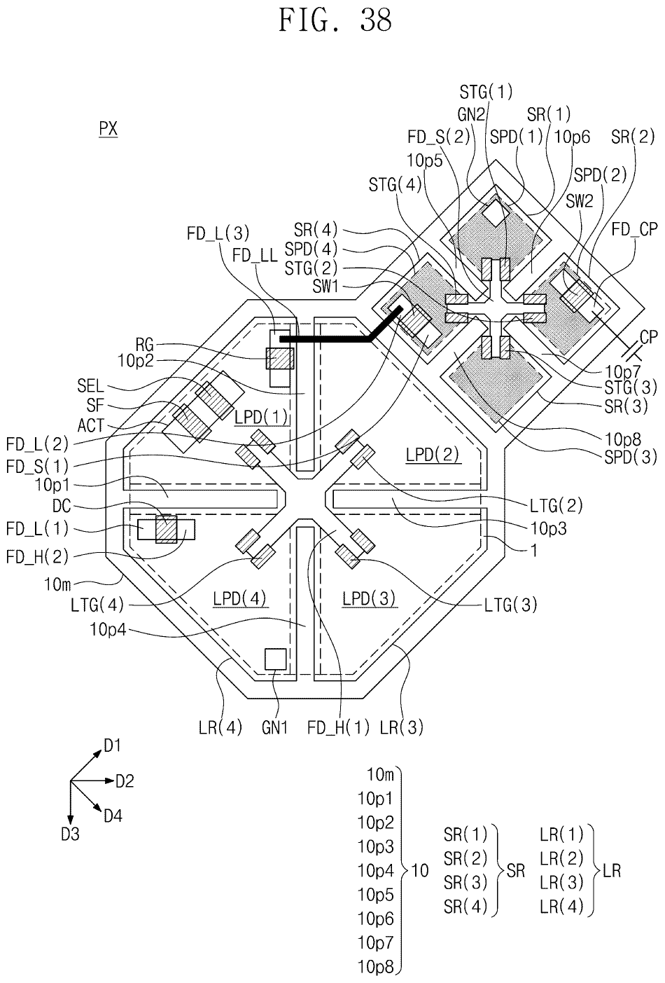

FIG. 38 is a layout illustrating an image sensor according to some example embodiments. The layout of FIG. 38 may correspond to one pixel PX of the pixel array of FIG. 25.

Referring to FIG. 38, the structure of the deep isolation pattern 10 and the arrangement of the transistors may be the same as those in FIG. 36. Concentrations of the second dopant in the first to fourth sub-small photoelectric conversion parts SPD(1) to SPD(4) may be higher than concentrations of the second dopant in the first to fourth sub-large photoelectric conversion parts LPD(1) to LPD(4).

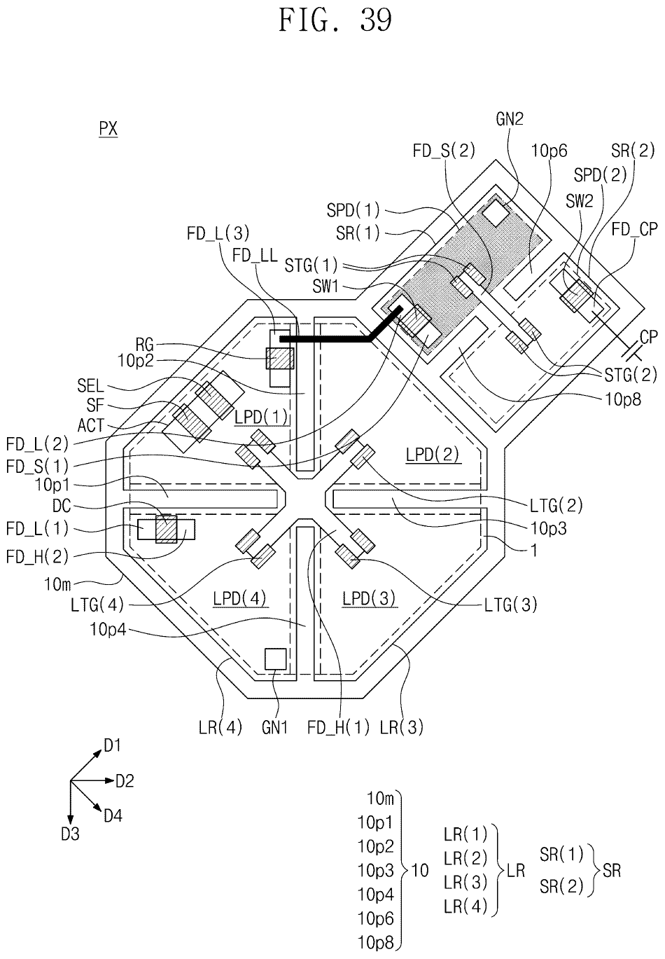

FIG. 39 is a layout illustrating an image sensor according to some example embodiments. The layout of FIG. 39 may correspond to one pixel PX of the pixel array of FIG. 25.

Referring to FIG. 39, in the image sensor in some example embodiments, the deep isolation pattern 10 may have substantially the same structure as that in FIG. 31. The sixth and eighth insertion isolation portions 10p6 and 10p8 may be inserted into the small light-receiving region SR to divide the small light-receiving region SR into two sub-small light-receiving regions SR(1) and SR(2). The first switch transistor WX1 including the first switch gate electrode SW1, the first SW1 dopant region FD_S1, and the second SW1 dopant region FD_L 2 may be disposed in the first sub-small light-receiving region SR(1). A concentration of the second dopant in the first sub-small photoelectric conversion part SPD(1) may be higher than concentrations of the second dopant in the second sub-small photoelectric conversion parts SPD(2) and the first to fourth sub-large photoelectric conversion parts LPD(1) to LPD(4). Except for the afore-described differences, the image sensor may have substantially the same features as that described with reference to FIGS. 31 and 33A.

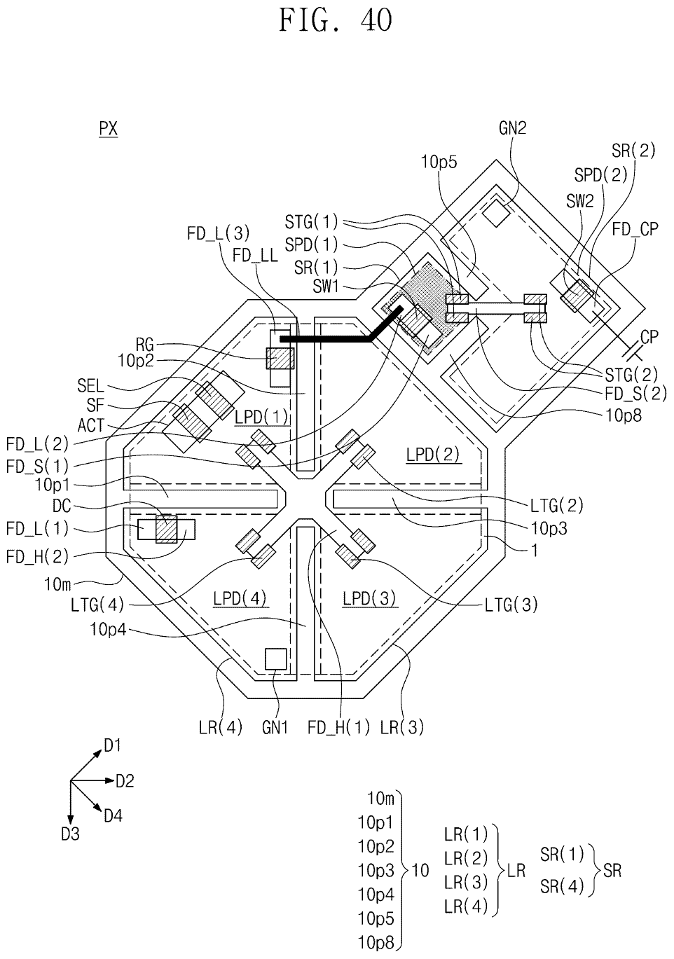

FIG. 40 is a layout illustrating an image sensor according to some example embodiments. The layout of FIG. 40 may correspond to one pixel PX of the pixel array of FIG. 25.

Referring to FIG. 40, in the image sensor in some example embodiments, the fifth and eighth insertion isolation portions 10p5 and 10p8 of the deep isolation pattern 10 may be inserted into the small light-receiving region SR to divide the small light-receiving region SR into two sub-small light-receiving regions SR(1) and SR(2). The second sub-small light-receiving region SR(2) may have an ‘L’ shape, when viewed in a plan view. Except for the afore-described differences, the image sensor may have substantially the same features as that described with reference to FIG. 39.

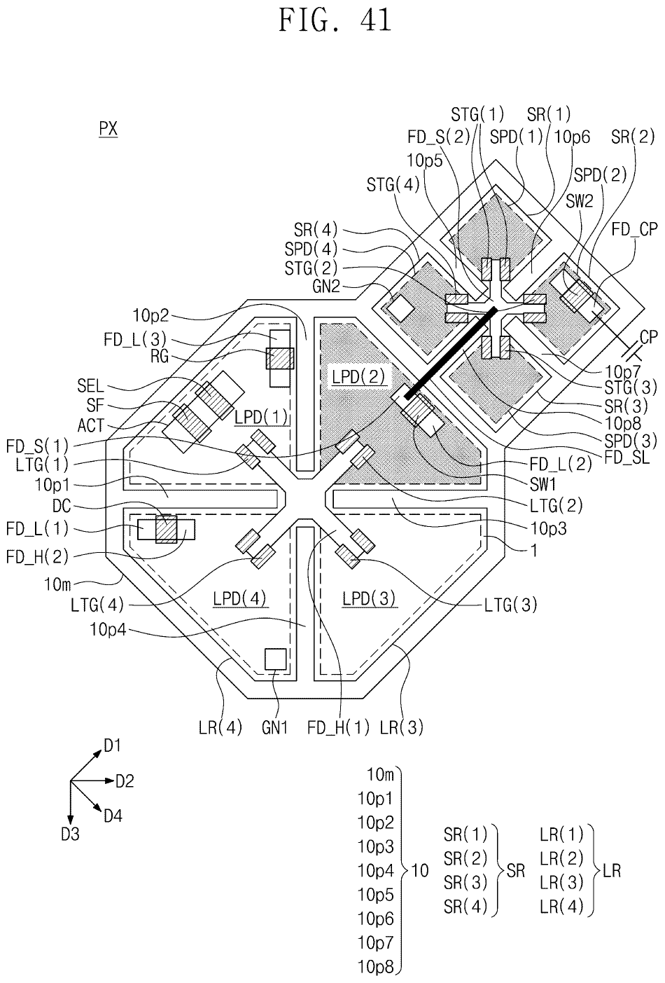

FIG. 41 is a layout illustrating an image sensor according to some example embodiments. The layout of FIG. 41 may correspond to one pixel PX of the pixel array of FIG. 25.

Referring to FIG. 41, the structure of the deep isolation pattern 10 and the arrangement of the transistors may be the same as those in FIG. 28. The concentration of the second dopant in the first to fourth sub-small photoelectric conversion parts SPD(1) to SPD(4) and the second sub-large photoelectric conversion part LPD(2) may be higher than the concentration of the second dopant in the first, third, and fourth sub-large photoelectric conversion parts LPD(1), LPD(3), and LPD(4).

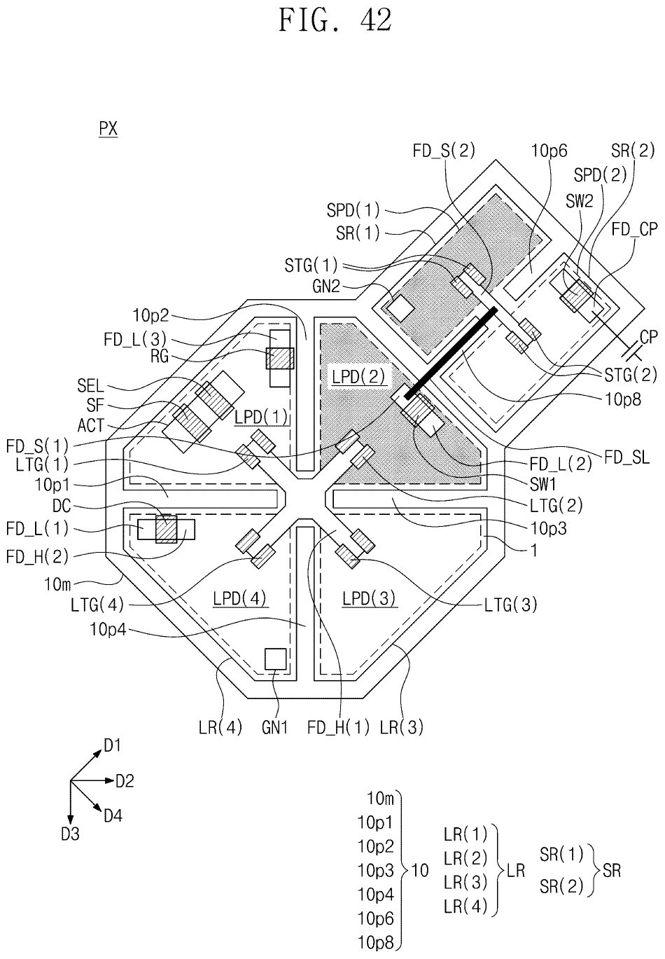

FIG. 42 is a layout illustrating an image sensor according to some example embodiments. The layout of FIG. 42 may correspond to one pixel PX of the pixel array of FIG. 25.

Referring to FIG. 42, the structure of the deep isolation pattern 10 and the arrangement of the transistors may be the same as those in FIG. 31. The concentration of the second dopant in the first sub-small photoelectric conversion part SPD(1) and the second sub-large photoelectric conversion part LPD(2) may be higher than the concentration of the second dopant in the second sub-small photoelectric conversion part SPD(2) and the first, third, and fourth sub-large photoelectric conversion parts LPD(1), LPD(3), and LPD(4).

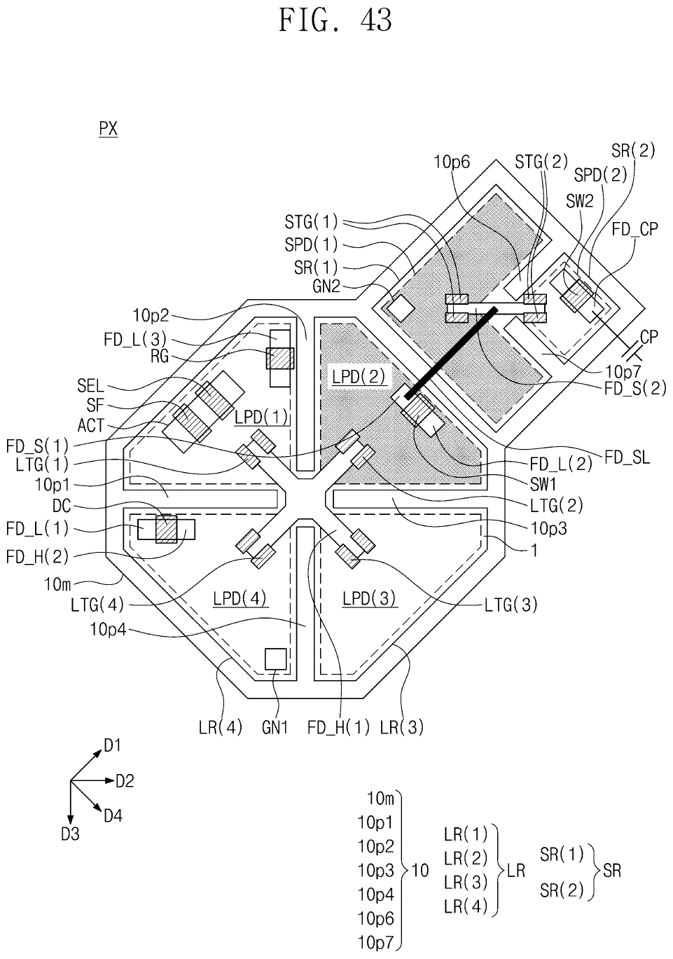

FIG. 43 is a layout illustrating an image sensor according to some example embodiments. The layout of FIG. 43 may correspond to one pixel PX of the pixel array of FIG. 25.

Referring to FIG. 43, in the image sensor in some example embodiments, the sixth and seventh insertion isolation portions 10p6 and 10p7 of the deep isolation pattern 10 may be inserted into the small light-receiving region SR to divide the small light-receiving region SR into two sub-small light-receiving regions SR(1) and SR(2). The first sub-small light-receiving region SR(1) may have an ‘L’ shape, when viewed in a plan view. Except for the afore-described differences, the image sensor may have substantially the same features as that described with reference to FIG. 42.

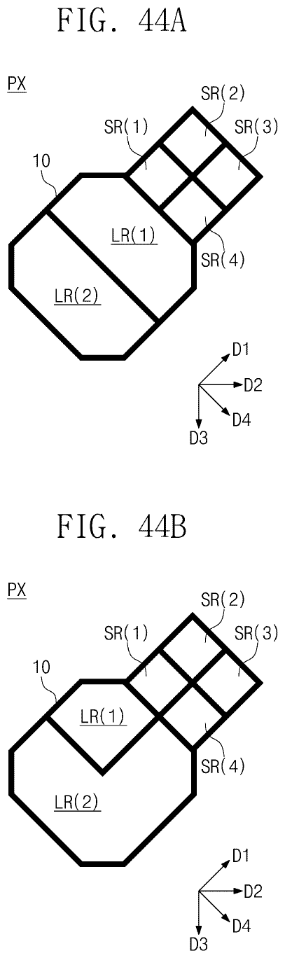

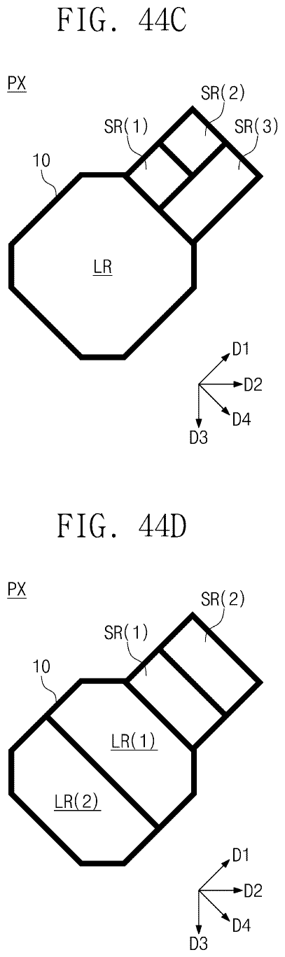

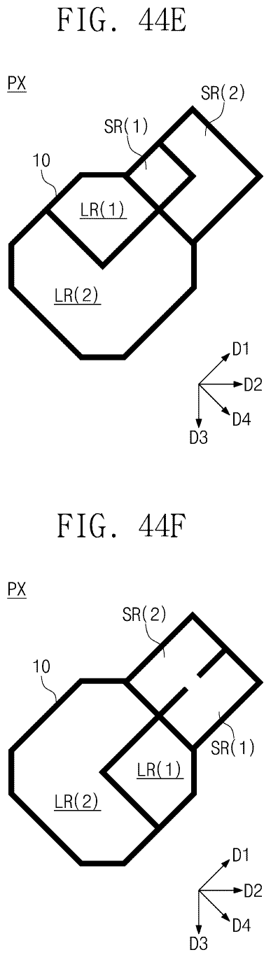

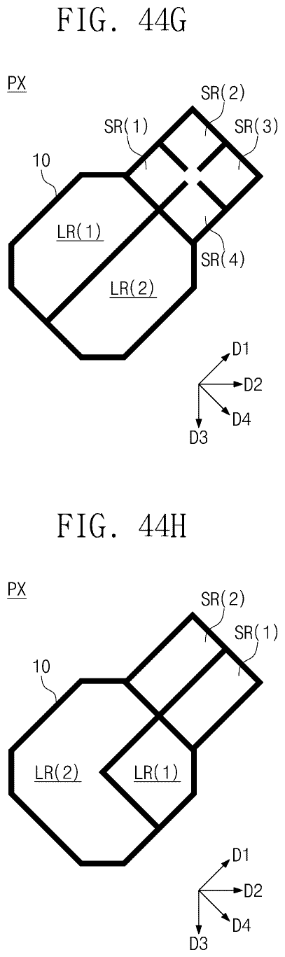

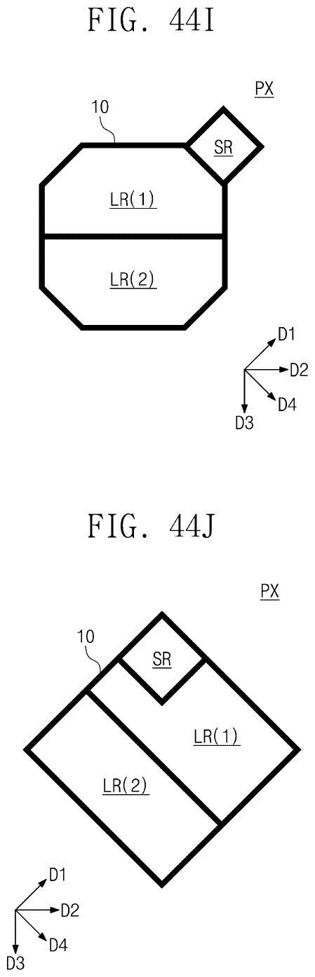

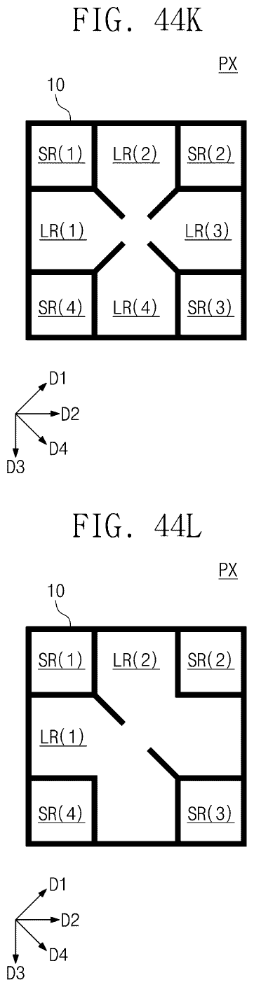

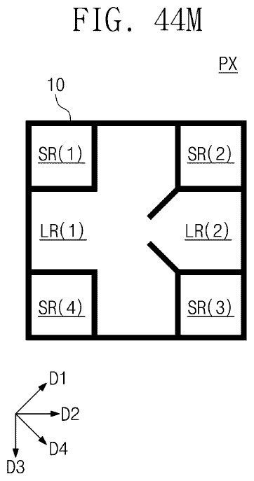

FIGS. 44A to 44M are layouts illustrating an image sensor according to some example embodiments. The layouts of FIGS. 44A to 44H may correspond to one pixel PX of the pixel array of FIG. 25. The layout of FIG. 441 may correspond to one pixel PX of the pixel array of FIG. 2. The layouts of FIGS. 44J to 44M may correspond to one pixel PX of the pixel array of FIG. 23.

Referring to FIGS. 44A to 44M, in the unit pixel PX of the image sensor according to some example embodiments, the deep isolation pattern 10 may have various shapes, and thus, the large and small light-receiving regions LR and SR may have various shapes. The large light-receiving region LR may be divided into two sub-large light-receiving regions LR(1) and LR(2), as shown in FIGS. 44A, 44B, 44D to 44J, 44L, and 44M. The large light-receiving region LR may be divided into four sub-large light-receiving regions LR(1) to LR(4), as shown in FIG. 44K.

The small light-receiving region SR may be divided into four sub-small light-receiving regions SR(1) to SR(4), as shown in FIGS. 44A, 44B, 44G, and 44K to 44M. The small light-receiving region SR may be divided into three sub-small light-receiving regions SR(1) to SR(3), as shown in FIG. 44C. The small light-receiving region SR may be divided into two sub-small light-receiving regions SR(1) and SR(2), as shown in FIGS. 44D to 44F and 44H.

A portion of the large light-receiving region LR and a portion of the small light-receiving region SR may be connected to the third node connection line FD_SL or second node connection line FD_SL. The large photoelectric conversion part LPD, which is disposed in the large light-receiving region LR, and/or at least a portion of the small photoelectric conversion part SPD, which is disposed in the small light-receiving region SR, may contain second dopants of a high concentration. Here, the first switch transistor WX1 may be disposed on the photoelectric conversion part LPD or SPD, which is doped with the second dopants of the high concentration. Alternatively, the buried region BL may be disposed in a portion of the large light-receiving region LR and the small light-receiving region SR. The image sensor according to the present example embodiment may have the same structure as that described above, and thus, it may be possible to improve the full well capacity (FWC) and to suppress the blooming phenomenon.

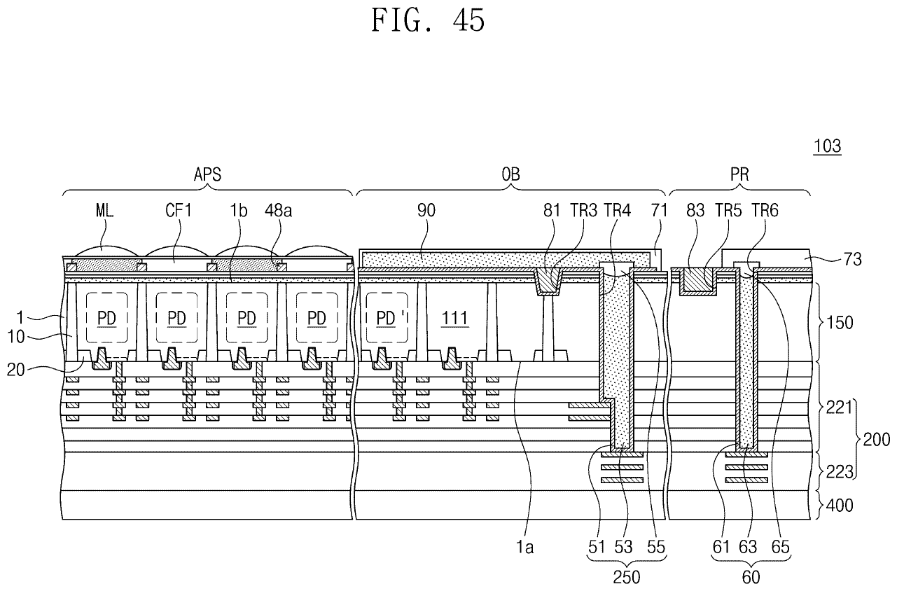

FIG. 45 is a sectional view illustrating an image sensor according to some example embodiments.

Referring to FIG. 45, an image sensor 103 according to some example embodiments may include the substrate 1, which has a pixel array region APS, an optical black region OB, and a pad region PR, an interconnection layer 200 on the first surface 1a of the substrate 1, and a base substrate 400 on the interconnection layer 200.

The interconnection layer 200 may include an upper interconnection layer 221 and a lower interconnection layer 223. The pixel array region APS may include the pixels PX described with reference to FIGS. 2 to 44M.

In the optical black region OB, a first connection structure 250, a first conductive pad 81, and a bulk color filter 90 may be provided on the substrate 1. The first connection structure 250 may include a first light-blocking pattern 51, an insulating pattern 53, and a first capping pattern 55. The first light-blocking pattern 51 may be formed of or include a conductive material. For example, the first light-blocking pattern 51 may be formed of or include titanium or tungsten.

The first light-blocking pattern 51 may be provided on the second surface 1b of the substrate 1. The first light-blocking pattern 51 may conformally cover inner surfaces of third and fourth trenches TR3 and TR4. The first light-blocking pattern 51 may be provided to penetrate a photoelectric conversion layer 150 and the upper interconnection layer 221 and to connect the photoelectric conversion layer 150 to the interconnection layer 200.

The first light-blocking pattern 51 may be in contact with the isolation conductive pattern 14 of the deep isolation pattern 10 of FIG. 3B. The first conductive pad 81 may be electrically connected to the isolation conductive pattern 14 of the deep isolation pattern 10. The first light-blocking pattern 51 may block light, which is incident into the optical black region OB.

The first conductive pad 81 may be provided in the third trench TR3 to fill a remaining portion of the third trench TR3. The first conductive pad 81 may be formed of or include at least one of metallic materials (e.g., aluminum). A negative bias voltage may be applied to the isolation conductive pattern 14 through the first conductive pad 81. In this case, it may be possible to prevent or suppress a white spot issue or a dark current issue.

The insulating pattern 53 may fill a remaining portion of the fourth trench TR4. The insulating pattern 53 may be formed to penetrate the photoelectric conversion layer 150 and the entirety or at least a portion of the interconnection layer 200. The first capping pattern 55 may be provided on a top surface of the insulating pattern 53. The first capping pattern 55 may be provided on the insulating pattern 53.

The bulk color filter 90 may be provided on the first conductive pad 81, a first light-blocking pattern 121, and a first capping pattern 125. The bulk color filter 90 may cover the first conductive pad 81, the first light-blocking pattern 51, and the first capping pattern 55. A first protection layer 71 may be provided on the bulk color filter 90 to hermetically seal the bulk color filter 90.

In some example embodiments, a plurality of pixels PX may also be disposed in the optical black region OB, and a first reference photoelectric conversion part PD′ and a second reference region 111 may be disposed in such pixels PX. The first reference photoelectric conversion part PD′ may be used to obtain a first reference charge amount, which is information on an amount of electric charges generated in a light-blocking state. The first reference charge amount may be used as a reference data for comparison with an amount of charges produced in each of the pixels PX. The second reference region 111 may be used to obtain a second reference charge amount, which is information on an amount of electric charges generated when the photoelectric conversion part PD is absent. The second reference charge amount may be used as information to remove a process noise.

In the pad region PR, a second connection structure 60, a second conductive pad 83, and a second protection layer 73 may be provided on the substrate 1. The second connection structure 60 may include a second light-blocking pattern 61, an insulating pattern 63, and a second capping pattern 65.

The second light-blocking pattern 61 may be provided on the second surface 1b of the substrate 1. The second light-blocking pattern 61 may conformally cover inner surfaces of fifth and sixth trenches TR5 and TR6. The second light-blocking pattern 61 may be provided to penetrate the photoelectric conversion layer 150 and the upper interconnection layer 221 and to connect the photoelectric conversion layer 150 to the interconnection layer 200. The second light-blocking pattern 61 may be in contact with the interconnection lines in the lower interconnection layer 223. The second light-blocking pattern 61 may be electrically connected to the interconnection lines in the interconnection layer 200. The second light-blocking pattern 61 may be formed of or include at least one of metallic materials (e.g., titanium or tungsten).

The second conductive pad 83 may be provided in the fifth trench TR5 to fill a remaining portion of the fifth trench TR5. The second conductive pad 83 may be formed of or include at least one of metallic materials (e.g., aluminum). The second conductive pad 83 may be used as a conduction path, which is used for electric connection to the outside of the image sensor. The insulating pattern 63 may fill a remaining portion of the sixth trench TR6. The insulating pattern 63 may be provided to penetrate the photoelectric conversion layer 150 and the entirety or at least a portion of the interconnection layer 200. The second capping pattern 65 may be provided on the insulating pattern 63. The second protection layer 73 may cover a portion of the second light-blocking pattern 61 and the second capping pattern 65.

In some example embodiments, one or more of the regions described as being doped with impurities of the first conductivity type may also be counterdoped, e.g., lightly doped, with impurities of the second conductivity type. Alternatively or additionally in some example embodiments, one or more regions described as being doped with impurities of the second conductivity type may also be counterdoped, e.g., lightly doped, with impurities of the second conductivity type. Alternatively or additionally, when a region is described as being doped with an impurity at a concentration higher than that of another region, a depth of impurities in the one region may be the same as, deeper than, or shallower than, a depth of impurities in the other region. Example embodiments are not limited thereto.

In the image sensor according to some example embodiments, at least a portion of a large photoelectric conversion part of a large light-receiving region and/or a small photoelectric conversion part of a small light-receiving region may contain second dopants of a high concentration. A buried region between a photoelectric conversion part and a floating diffusion region may be provided in the large light-receiving region and/or the small light-receiving region. Thus, it may be possible to prevent or reduce a blooming phenomenon between the large light-receiving region and the small light-receiving region.

Alternatively or additionally, in the image sensor according to some example embodiments, by dividing the large light-receiving region and/or the small light-receiving region into a plurality of sub-regions, it may be possible to increase a full well capacity (FWC). This may make it possible to improve a signal-to-noise ratio (SNR) property and to realize a sharp image with high dynamic range (HDR).

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While some example embodiments of the inventive concept have been particularly shown and described, it will be understood by one of ordinary skill in the art that variations in form and detail may be made therein without departing from the spirit and scope of the attached claims. Various example embodiments described with reference to FIGS. 1 to 45 may be combined to realize the inventive concept of some example embodiments. For example, example embodiments are not necessarily mutually exclusive with one another. Some example embodiments may include one or more features described with reference to one or more figures, and may also include one or more other features described with reference to one or more other figures.

What is claimed is:

1. An image sensor, comprising:
a substrate having a first surface and a second surface opposite to each other;
a deep isolation pattern in the substrate and defining a large light-receiving region and a small light-receiving region separated from each other, the large light-receiving region being adjacent to the small light-receiving region;
a first large photoelectric conversion part in the substrate and in the large light-receiving region;
a small photoelectric conversion part in the substrate and in the small light-receiving region;
a first dopant region in the substrate to be adjacent to the first surface, the first dopant region in the large light-receiving region;
a second dopant region in the substrate and adjacent to the first surface, the second dopant region in the small light-receiving region; and
a first connection line connecting the first dopant region to the second dopant region,
wherein the first large photoelectric conversion part and the small photoelectric conversion part are doped with first dopants of a first conductivity type, and
a concentration of the first dopants of the first large photoelectric conversion part is different from a concentration of the first dopants of the small photoelectric conversion part.

2. The image sensor of claim 1, further comprising:
a first color filter on the second surface and covering the large light-receiving region and the small light-receiving region.

3. The image sensor of claim 1, further comprising:
a large transfer gate electrode in the large light-receiving region, on the first surface, and partially inserted into the substrate;
a large floating diffusion region in the substrate;
a buried region between the large floating diffusion region and the first large photoelectric conversion part; and
a well region between the first dopant region and the first large photoelectric conversion part,
wherein the well region and the buried region are doped with second dopants, which has a second conductivity type different from the first conductivity type, and
a concentration of the second dopants in the buried region is less than a concentration of the second dopants in the well region.

4. The image sensor of claim 3, wherein the buried region further comprises the first dopants.

5. The image sensor of claim 1, wherein
the deep isolation pattern extends to be inserted into the large light-receiving region and divides the large light-receiving region into first and second sub-large light-receiving regions,
the first sub-large light-receiving region is adjacent to the small light-receiving region,
the first large photoelectric conversion part is in the first sub-large light-receiving region,
the image sensor further comprises a second large photoelectric conversion part in the substrate and in the second sub-large light-receiving region,
the second large photoelectric conversion part is doped with the first dopants, and
a concentration of the first dopants in the first large photoelectric conversion part is higher than a concentration of the first dopants in the second large photoelectric conversion part.

6. The image sensor of claim 5, wherein an area of the second sub-large light-receiving region is ¼ to ¾ of an area of the large light-receiving region.

7. The image sensor of claim 1, wherein the deep isolation pattern extends to be inserted into the large light-receiving region and divides large light-receiving region into two to four sub-large light-receiving regions.

8. The image sensor of claim 1, wherein the deep isolation pattern extends to be inserted into the small light-receiving region and to divide the small light-receiving region into a plurality of sub-small light-receiving regions.

9. The image sensor of claim 8, wherein
the large light-receiving region has an octagonal shape with alternatively and repeatedly arranged first side surfaces and second side surfaces, when viewed in a plan view,
each of the first side surfaces has a first length,
each of the second side surfaces has a second length longer than the first length,
the small light-receiving region is adjacent to one of the second side surfaces,
the small light-receiving region has a square shape composed of third side surfaces, when viewed in a plan view, and
the third side surfaces has a third length that is equal to or smaller than the second length.

10. The image sensor of claim 1, wherein
the first large photoelectric conversion part comprises a high concentration photoelectric conversion part and a low concentration photoelectric conversion part, which are in contact with each other,
the high concentration photoelectric conversion part and the low concentration photoelectric conversion part are doped with the first dopants, and
a concentration of the first dopants in the high concentration photoelectric conversion part is different from a concentration of the first dopants in the low concentration photoelectric conversion part.

11. An image sensor, comprising:
a substrate having a first surface and a second surface opposite to each other;
a deep isolation pattern in the substrate and defining a large light-receiving region and a small light-receiving region separated from each other, the large light-receiving region adjacent to the small light-receiving region;
a first color filter on the second surface and covering the large light-receiving region and the small light-receiving region;
a first micro lens on the first color filter and covering the large light-receiving region;
a second micro lens on the first color filter and covering the small light-receiving region;
a first large photoelectric conversion part in the substrate and in the large light-receiving region;
a small photoelectric conversion part in the substrate and in the small light-receiving region;
a first dopant region in the substrate, in the large light-receiving region, and adjacent to the first surface;
a second dopant region disposed in the substrate, in the small light-receiving region, and adjacent to the first surface;
a first connection line connecting the first dopant region to the second dopant region;
a large transfer gate electrode in the large light-receiving region and on the first surface and partially inserted into the substrate;
a large floating diffusion region in the substrate;
a buried region disposed between the large floating diffusion region and the first large photoelectric conversion part; and
a well region between the first dopant region and the first large photoelectric conversion part,
wherein the first large photoelectric conversion part and the small photoelectric conversion part are doped with first dopants of a first conductivity type,
the well region and the buried region are doped with second dopants, which have a second conductivity type different from the first conductivity type, and
a concentration of the second dopants in the buried region is lower than a concentration of the second dopants in the well region.

12. The image sensor of claim 11, wherein a concentration of the first dopants in the first large photoelectric conversion part is different from a concentration of the first dopants in the small photoelectric conversion part.

13. The image sensor of claim 11, wherein the buried region further comprises the first dopants.

14. The image sensor of claim 11, wherein
the deep isolation pattern extends to be inserted into the large light-receiving region and divides the large light-receiving region into first and second sub-large light-receiving regions,
the first sub-large light-receiving region is adjacent to the small light-receiving region,
the first large photoelectric conversion part is in the first sub-large light-receiving region,
the image sensor further comprises a second large photoelectric conversion part, in the substrate and in the second sub-large light-receiving region,
the second large photoelectric conversion part is doped with the first dopants, and
a concentration of the first dopants in the first large photoelectric conversion part is greater than a concentration of the first dopants in the second large photoelectric conversion part.

15. The image sensor of claim 14, wherein an area of the second sub-large light-receiving region is ¼ to ¾ of an area of the large light-receiving region.

16. The image sensor of claim 11, wherein the deep isolation pattern extends to be inserted into the small light-receiving region and divides the small light-receiving region into a plurality of sub-small light-receiving regions.

17. An image sensor, comprising:
a substrate having a first surface and a second surface opposite to each other;
a deep isolation pattern in the substrate and defining a large light-receiving region and a small light-receiving region separated from each other, the large light-receiving region adjacent to the small light-receiving region;
a first dopant region in the substrate, in the large light-receiving region, and adjacent to the first surface;
a second dopant region in the substrate, in the small light-receiving region, and adjacent to the first surface; and
a first connection line connecting the first dopant region to the second dopant region,
wherein an area of the large light-receiving region is larger than an area of the small light-receiving region, and
the deep isolation pattern extends to be inserted into the small light-receiving region and divides the small light-receiving region into a plurality of sub-small light-receiving regions.

18. The image sensor of claim 17, further comprising:
a small photoelectric conversion part in the substrate and in one of the sub-small light-receiving regions;
a small transfer gate electrode on the small photoelectric conversion part;
a small floating diffusion region in the substrate;
a buried region between the small floating diffusion region and the small photoelectric conversion part; and
a well region between the second dopant region and the small photoelectric conversion part,
wherein the small photoelectric conversion part and the small floating diffusion region are doped with first dopants of a first conductivity type,
the well region and the buried region are doped with second dopants, which have a second conductivity type different from the first conductivity type, and
a concentration of the second dopants in the buried region is less than a concentration of the second dopants in the well region.

19. The image sensor of claim 18, further comprising:
a large photoelectric conversion part in the substrate and in the large light-receiving region,
wherein the large photoelectric conversion part is doped with the first dopants, and
a concentration of the first dopants in the large photoelectric conversion part is different from a concentration of the first dopants in the small photoelectric conversion part.

20. The image sensor of claim 17, wherein the deep isolation pattern extends to be inserted into the large light-receiving region and divides the large light-receiving region into a plurality of sub-large light-receiving regions.
